(19) United States
(12) Patent Application Publication
(10) Pub. No.: US 2024/0337007 A1
(43) Pub. Date: Oct. 10, 2024

(54) Environmentally Friendly Decorative Chrome-Like Materials And Methods Of Making The Same

(71) Applicant: THE REGENTS OF THE UNIVERSITY OF MICHIGAN, Ann Arbor, MI (US)

(72) Inventors: Lingjie Jay GUO, Ann Arbor, MI (US); Haozhu WANG, Mount Prospect, IL (US); Taigao MA, Ann Arbor, MI (US)

(73) Assignee: THE REGENTS OF THE UNIVERSITY OF MICHIGAN, Ann Arbor, MI (US)

(21) Appl. No.: 18/629,055

(22) Filed: Apr. 8, 2024

Related U.S. Application Data
(60) Provisional application No. 63/457,612, filed on Apr. 6, 2023.

(51) Int. Cl. C23C 14/18; C23C 14/08; C23C 14/10; C23C 14/30

(52) U.S. Cl. CPC C23C 14/18; C23C 14/083; C23C 14/10; C23C 14/30

(57) ABSTRACT

A material having a chrome-like appearance includes a substrate and a multilayer stack with at least three material layers, each is independently selected from the group consisting of: germanium (Ge), titanium oxide (TiO₂), silicon dioxide (SiO₂), titanium (Ti), nickel (Ni), aluminum (Al), aluminum oxide (Al₂O₃), silver (Ag), gold (Au), magnesium fluoride (MgF₂), magnesium oxide (MgO), silicon (Si), silicon oxide (SiO₂), silicon carbide (SiC), tungsten (W), hafnium oxide (HfO₂), zinc (Zn), zinc oxide (ZnO), zinc sulfide (ZnS), zinc selenide (ZnSe), chalcogenides, iron oxide (Fe₂O₃) and combinations thereof. The material is free of chromium (Cr) and displays a specular reflectivity such that ≥ about 70% of wavelengths in a visible light range of 390 to 750 nm are reflected without scattering. In certain variations, a radiofrequency (RF)-transparent material having a chrome-like appearance is free of any metals. Methods of making the materials having the chrome-like appearance are also provided.

### CROSS-REFERENCE TO RELATED APPLICATIONS

This application claims the benefit of U.S. Provisional Application No. 63/457,612, filed on Apr. 6, 2023. The entire disclosure of the above application is incorporated herein by reference.

### GOVERNMENT SUPPORT

This invention was made with government support under 2213684 awarded by the National Science Foundation. The government has certain rights in the invention.

### FIELD

The present disclosure relates to environmentally friendly materials having a chrome-like appearance that include a substrate and a multilayer stack that exhibit specular reflectivity and methods for making the same.

### BACKGROUND

This section provides background information related to the present disclosure which is not necessarily prior art.

Chromium-based “chrome” plating has been ubiquitous in metal finishings and coatings. For example, Decorative Chrome Plating (DCP) is a metal finishing process widely used in industry for metal finishings, coatings, and trim, for example, being used as a coating for various automobile parts, kitchen appliances, plumbing fixtures, and the like because of its distinct aesthetic and shiny reflecting appearance. During a plating process for depositing chromium layers, the plating surface is submerged in a chemical electrolyte containing hexavalent chromium (Cr(VI)) or trivalent chromium (Cr(III)). The application of a potential difference in the solution results in the transport and subsequent deposition of chromium ions on the object being coated.

However, the industrial processes for handling and depositing chromium, like chromium electroplating, are hazardous due to potential adverse health effects for those that come into contact with chromium-containing materials (e.g., the workers involved) and the need for extensive environmental precautions to avoid or minimize environmental pollution. This is especially true for processes that involve hexavalent chrome (Cr(VI)). Hexavalent chromium (Cr(VI)) is a strong human carcinogen and has been found to greatly increase the risk of lung, nasal, and sinus cancer in workers who are exposed to Cr(VI) mist generated during the plating process. Cr(VI) can also cause severe nasal septum ulcerations and perforations, gastritis, and gastrointestinal ulcers. Toxic emissions containing cadmium and cyanide released during the electroplating process can also lead to air pollution, which could impact the health of millions of people. Given this hazard, the adverse health impacts significantly outweigh the aesthetic benefits of Cr(VI), so there is a significant impetus to find an alternative to replace this process.

Trivalent chromium, Cr(III) is less toxic than Cr(VI) and thus has been considered as an alternative to Cr(VI) for decorative plating applications. However, anodic oxidation of Cr(III) to Cr(VI) and the formation of stable Cr(III) coordinates in aqueous solutions makes the plating process complex due to the need for maintaining a constant pH. Non-electrolytic substitutes for chromium deposition, including high-velocity oxygen-fuel (HVOF) thermal spraying and laser material deposition (LMD) have also been developed. However, both processes still utilize chromium and can use environmentally harmful chemicals.

Decorative chromium coatings are often found on vehicle bodies, especially emblems. Despite the attractive appearance, such shiny metal-based emblems block the radio frequency transmission needed for many vehicle sensors. Finding alternative chromium-free materials that have a chrome-like reflective appearance has been challenging. The reflective appearance of chrome plating (e.g., DCP) is unique, especially to the human eye, and very difficult to replicate with materials that do not contain chromium. Designing optical structures for generating structural colors is challenging because of the complex relationship between the optical structures and the color or appearance perceived by human eyes. Therefore, it would be desirable to eliminate the usage of chromium (metal) while still preserving its attractive and uniquely reflective appearance. Further, it would be desirable to develop a material having a chrome-like appearance that can transmit radio frequency transmissions in applications where it is advantageous.

### SUMMARY

This section provides a general summary of the disclosure, and is not a comprehensive disclosure of its full scope or all of its features.

In certain aspects the present disclosure relates to a material having a chrome-like appearance. The material comprises a substrate and a multilayer stack disposed on the substrate that comprises at least three material layers. At least two material layers of the multilayer stack are compositionally distinct from one another. Each material layer independently comprises a composition selected from a first composition comprising an optically transparent dielectric material selected from the group consisting of: titanium oxide (TiO₂), silicon dioxide (SiO₂), magnesium fluoride (MgF₂), magnesium oxide (MgO), aluminum oxide (Al₂O₃), hafnium oxide (HfO₂), zirconium dioxide (ZrO₂), zinc sulfide (ZnS), zinc selenide (ZnSe), zinc oxide (ZnO), silicon nitride (Si₃N₄), silicon dioxide (SiO₂), tin oxide (SnO₂), and combinations thereof, a second composition comprising a light absorbing material comprising an element selected from Groups 13 to 16 of the IUPAC Periodic Table, or a third composition comprising a light reflecting material selected from the group consisting of: nickel (Ni), aluminum (Al), copper (Cu), silver (Ag), gold (Au), tungsten (W), zinc (Zn), platinum (Pt), titanium (Ti), titanium nitride (TiN), and combinations thereof. The material is free of chromium (Cr) and displays a specular reflectivity such that greater than or equal to about 50% of wavelengths in a visible light range of greater than or equal to about 390 nm to less than or equal to about 750 nm are reflected by the material without scattering.

In one aspect, the second composition comprises a light absorbing material selected from the group consisting of: silicon (Si), germanium (Ge), silicon carbide (SiC), gallium nitride (GaN), gallium phosphide (GaP), zinc sulfide (ZnS), zinc selenide (ZnSe), iron oxides, chalcogenides, and combinations thereof.

In one aspect, the multilayer stack defines a first side adjacent to the substrate and a second side opposite to the first side defining a terminal material layer. The terminal material layer comprises the third composition comprising the light reflecting material and the multilayer stack further comprises one or more intermediate material layers comprising the first composition comprising the optically transparent dielectric material disposed between the terminal material layer and the substrate.

In one aspect, the material further comprises at least one second intermediate material layer disposed between the substrate and the terminal material layer that comprises the second composition comprising the light absorbing material disposed between the terminal material layer and the substrate.

In one aspect, the multilayer stack comprises one of the following:
(a) three distinct material layers, where a first material layer adjacent to the substrate comprises silicon nitride (Si₃N₄), a second material layer comprises silicon (Si), and the terminal material layer comprises aluminum (Al); or
(b) three distinct material layers, where a first material layer adjacent to the substrate comprises zinc sulfide (ZnS), a second material layer comprises magnesium fluoride (Mg₂F), and the terminal material layer comprises silver (Ag); or
(c) four distinct material layers, where a first material layer adjacent to the substrate comprises aluminum oxide (Al₂O₃), a second material layer comprises magnesium oxide (MgO), a third material layer comprises titanium dioxide (TiO₂), and the terminal material layer comprises aluminum (Al).

In one aspect, the multilayer stack defines a first side adjacent to the substrate and a second side opposite to the first side defining a terminal material layer. The terminal material layer comprises the second composition comprising the light absorbing material and the multilayer stack further comprises one or more intermediate material layers disposed between the terminal material layer and the substrate and comprising the first composition comprising the optically transparent dielectric material.

In one aspect, the material further comprises at least one intermediate material layer disposed between the terminal material layer and the substrate comprising the second composition comprising the light absorbing material.

In one further aspect, the first side of the multilayer stack comprises a bottom material layer adjacent to the substrate that comprises the third composition comprising the light reflecting material.

In one aspect, the multilayer stack comprises one of the following:
(a) three distinct material layers, where a first material layer adjacent to the substrate comprises germanium (Ge), a second material layer comprises silicon dioxide (SiO₂), and the terminal material layer comprises germanium (Ge);
(b) four distinct material layers, where a first material layer adjacent to the substrate comprises nickel (Ni), a second material layer comprises silicon dioxide (SiO₂), a third material layer comprises titanium dioxide (TiO₂), and the terminal material layer comprises germanium (Ge); or
(c) four distinct material layers, where a first material layer adjacent to the substrate comprises silver (Ag), a second material layer comprises tin oxide (SnO₂), a third material layer comprises magnesium fluoride (MgF₂), and the terminal material layer comprises silicon (Si).

In one aspect, the multilayer stack defines a first side defining a bottom material layer adjacent to the substrate and a second side opposite to the first side defining a terminal material layer. The terminal material layer comprises the first composition comprising the optically transparent dielectric material and the bottom material layer comprises the third composition comprising the light reflecting material.

In one aspect, the multilayer stack further comprises at least one intermediate material layer disposed between the bottom material layer and the terminal material layer comprising the first composition comprising the optically transparent dielectric material.

In one further aspect, the multilayer stack further comprises at least one intermediate material layer disposed between the bottom material layer and the terminal material layer comprising the second composition comprising the light absorbing material.

In one aspect, the multilayer stack comprises one of the following:
(a) three distinct material layers, where a first material layer adjacent to the substrate comprises germanium (Ge), a second material layer comprises aluminum (Al), and the terminal material layer comprises magnesium fluoride (MgF₂);
(b) three distinct material layers, where a first material layer adjacent to the substrate comprises aluminum (Al), a second material layer comprises silicon dioxide (SiO₂), and the terminal material layer comprises zinc oxide (ZnO);
(c) three distinct material layers, where a first material layer adjacent to the substrate comprises silver (Ag), a second material layer comprises zinc selenide (ZnSe), and the terminal material layer comprises zinc oxide (ZnO);
(d) four distinct material layers, where a first material layer adjacent to the substrate comprises aluminum (Al), a second material layer comprises aluminum oxide (Al₂O₃), a third material layer comprises aluminum (Al), and the terminal material layer comprises aluminum oxide (Al₂O₃);
(e) five distinct material layers, where a first material layer adjacent to the substrate comprises aluminum oxide (Al₂O₃), a second material layer comprises aluminum (Al), a third material layer comprises silicon dioxide (SiO₂), a fourth material layer comprises magnesium fluoride (MgF₂), and the terminal material layer comprises silicon dioxide (SiO₂).
(f) five distinct material layers, where a first material layer adjacent to the substrate comprises gold (Au), a second material layer comprises magnesium fluoride (MgF₂), a third material layer comprises germanium (Ge), a fourth material layer comprises zinc (Zn), and the terminal material layer comprises hafnium oxide (HfO₂);
(g) five distinct material layers, where a first material layer adjacent to the substrate comprises gold (Au), a second material layer comprises aluminum oxide (Al₂O₃), a third material layer comprises germanium (Ge), a fourth material layer comprises zinc (Zn), and the terminal material layer comprises hafnium oxide (HfO₂);
(h) five distinct material layers, where a first layer adjacent to the substrate comprises gold (Au), a second material layer comprises silicon dioxide (SiO₂), a third material layer comprises germanium (Ge), a fourth material layer comprises silver (Ag), and the terminal material layer comprises silicon dioxide (SiO₂);
(i) five distinct material layers, where a first material layer adjacent to the substrate comprises nickel (Ni), a second material layer comprises aluminum oxide (Al₂O₃), a third material layer comprises germanium (Ge), a fourth material layer comprises zinc (Zn), and the terminal material layer comprises hafnium oxide (HfO₂);
(j) five distinct material layers, where a first material layer adjacent to the substrate comprises zinc (Zn), a second material layer comprises silicon dioxide (SiO₂), a third material layer comprises germanium (Ge), a fourth material layer comprises tungsten (W), and the terminal material layer comprises hafnium oxide (HfO₂);
(k) five distinct material layers, where a first layer adjacent to the substrate comprises aluminum oxide (Al₂O₃), a second layer comprises aluminum (Al), a third layer comprises silicon dioxide (SiO₂), a fourth layer comprises magnesium fluoride (MgF₂), and the terminal material layer comprises silicon dioxide (SiO₂);
(l) five distinct material layers, where a first layer adjacent to the substrate comprises gold (Au), a second layer comprises magnesium fluoride (MgF₂), a third layer comprises germanium (Ge), a fourth layer comprises zinc (Zn), and the terminal material layer comprises hafnium oxide (HfO₂);
(m) five distinct material layers, where a first layer adjacent to the substrate comprises gold (Au), a second layer comprises aluminum oxide (Al₂O₃), a third layer comprises germanium (Ge), a fourth layer comprises zinc (Zn), and the terminal material layer comprises hafnium oxide (HfO₂);
(n) five distinct material layers, where a first layer adjacent to the substrate comprises gold (Au), a second layer comprises silicon dioxide (SiO₂), a third layer comprises germanium (Ge), a fourth layer comprises silver (Ag), and the terminal material layer comprises silicon dioxide (SiO₂);
(o) five distinct material layers, where a first layer adjacent to the substrate comprises nickel (Ni), a second layer comprises aluminum oxide (Al₂O₃), a third layer comprises germanium (Ge), a fourth layer comprises zinc (Zn), and the terminal material layer comprises hafnium oxide (HfO₂); or
(p) five distinct material layers, where a first layer adjacent to the substrate comprises zinc (Zn), a second layer comprises silicon dioxide (SiO₂), a third layer comprises germanium (Ge), a fourth layer comprises tungsten (W), and the terminal material layer comprises hafnium oxide (HfO₂).

In one aspect, the specular reflectivity is such that greater than or equal to about 70% of wavelengths in the visible light range of greater than or equal to about 390 nm to less than or equal to about 750 nm are reflected by the material without scattering.

In one aspect, greater than or equal to about 50% of light reflected from the material has the same band of wavelengths.

In one aspect, light reflected from the material exhibits a peak range of wavelengths corresponding to a hue.

In one aspect, the multilayer stack defines a first side adjacent to the substrate and a second side opposite to the first side defining a terminal material layer. The material further comprises a protective coating disposed on the terminal material layer of the multilayer stack, wherein the protective coating is transparent to electromagnetic radiation in the visible light range.

In one aspect, each of the material layers has an average thickness of greater than or equal to about 15 nm to less than or equal to about 150 nm.

In one aspect, the substrate is selected from the group consisting of: polymer, a metal, an inorganic dielectric material, and combinations thereof.

In one aspect, the multilayer stack comprises between three and five distinct material layers.

In certain aspects the present disclosure further relates to a radiofrequency (RF)-transparent material having a chrome-like appearance. The material may comprise a substrate that displays a transparency to radiofrequency (RF) electromagnetic radiation of greater than or equal to about 60% of wavelengths of greater than or equal to about 1 mm to less than or equal to about 10 m are transmitted. The material also comprises a multilayer stack disposed on the substrate that comprises at least three material layers, wherein at least two material layers are compositionally distinct from one another. Each material layer is independently a composition selected from a first composition comprising an optically transparent dielectric material selected from the group consisting of: titanium oxide (TiO₂), silicon dioxide (SiO₂), magnesium fluoride (MgF₂), magnesium oxide (MgO), aluminum oxide (Al₂O₃), hafnium oxide (HfO₂), zirconium dioxide (ZrO₂), zinc sulfide (ZnS), zinc selenide (ZnSe), zinc oxide (ZnO), silicon nitride (Si₃N₄), silicon dioxide (SiO₂), tin oxide (SnO₂), and combinations thereof and/or a second composition comprising a light absorbing material comprising an element selected from Groups 13 to 16 of the IUPAC Periodic Table. The material is free of any metals, displays a specular reflectivity where greater than or equal to about 50% of wavelengths in a visible light range of greater than or equal to about 390 nm to less than or equal to about 750 nm are reflected by the material without scattering, and displays a transparency to radiofrequency (RF) electromagnetic radiation where greater than or equal to about 60% of wavelengths of greater than or equal to about 1 mm to less than or equal to about 10 m are transmitted.

In one aspect, the second composition comprises a light absorbing material selected from the group consisting of: silicon (Si), germanium (Ge), silicon carbide (SiC), gallium nitride (GaN), gallium phosphide (GaP), zinc sulfide (ZnS), zinc selenide (ZnSe), iron oxides, chalcogenides, and combinations thereof.

In one aspect, each of the material layers has a thickness of greater than or equal to about 15 nm to less than or equal to about 150 nm.

In one aspect, the multilayer stack comprises three distinct material layers, where a first material layer is disposed on the substrate and comprises germanium (Ge), a second material layer is disposed over the first layer and comprises silicon dioxide (SiO₂), and a third terminal material layer is disposed over the second layer and comprises germanium (Ge).

In one aspect, a first material layer is disposed on the substrate and comprises germanium (Ge) and has a first average thickness of about 33 nm, a second material layer comprises silicon dioxide (SiO₂) disposed on the first material layer and has a second average thickness of about 119 nm, and a third layer comprises germanium (Ge) disposed on the second layer that has a third average thickness of about 21 nm.

In one aspect, the radiofrequency (RF)-transparent material further comprises a protective coating disposed over a terminal end of the multilayer stack that is transparent to electromagnetic radiation in the visible light range.

In one aspect, the substrate is selected from the group consisting of: polymer, a metal, an inorganic dielectric material, and combinations thereof.

In one aspect, a device comprises such a radiofrequency (RF)-transparent material. The device may be selected from the group consisting of: a decoration, a vehicle component, trim, a consumer product, a mobile device, a wall, a section of a wall, a security device, and combinations thereof.

In certain aspects the present disclosure also relates to a material having a chrome-like appearance comprising a substrate and a multilayer stack disposed on the substrate that comprises at least three material layers. At least two material layers are compositionally distinct from one another. Each material layer independently comprises a composition selected from a first composition comprising an optically transparent dielectric material selected from the group consisting of: titanium oxide (TiO₂), silicon dioxide (SiO₂), magnesium fluoride (MgF₂), magnesium oxide (MgO), aluminum oxide (Al₂O₃), hafnium oxide (HfO₂), zirconium dioxide (ZrO₂), zinc sulfide (ZnS), zinc selenide (ZnSe), zinc oxide (ZnO), silicon nitride (Si₃N₄), silicon dioxide (SiO₂), tin oxide (SnO₂), and combinations thereof, a second composition comprising a light absorbing material comprising an element selected from Groups 13 to 16 of the IUPAC Periodic Table, a third composition comprising a light reflecting material selected from the group consisting of: nickel (Ni), aluminum (Al), copper (Cu), silver (Ag), gold (Au), tungsten (W), zinc (Zn), platinum (Pt), titanium (Ti), titanium nitride (TiN), and combinations thereof, or a fourth composition comprising chromium (Cr). The material may display a specular reflectivity such that greater than or equal to about 70% of wavelengths in a visible light range of greater than or equal to about 390 nm to less than or equal to about 750 nm are reflected by the material without scattering.

In certain further aspects, the present disclosure relates to a method of making a material having a chrome-like appearance. The method comprises depositing at least three material layers on a substrate via a physical vapor deposition process to form a multilayer stack. At least two material layers are compositionally distinct from one another. Each material layer independently comprises a composition selected from a first composition comprising an optically transparent dielectric material selected from the group consisting of: titanium oxide (TiO₂), silicon dioxide (SiO₂), magnesium fluoride (MgF₂), magnesium oxide (MgO), aluminum oxide (Al₂O₃), hafnium oxide (HfO₂), zirconium dioxide (ZrO₂), zinc sulfide (ZnS), zinc selenide (ZnSe), zinc oxide (ZnO), silicon nitride (Si₃N₄), silicon dioxide (SiO₂), tin oxide (SnO₂), and combinations thereof, a second composition comprising a light absorbing material selected from the group consisting of: silicon (Si), germanium (Ge), silicon carbide (SiC), gallium nitride (GaN), gallium phosphide (GaP), zinc sulfide (ZnS), zinc selenide (ZnSe), chalcogenides, iron oxides, and combinations thereof, or a third composition comprising a light reflecting material selected from the group consisting of: nickel (Ni), aluminum (Al), copper (Cu), silver (Ag), gold (Au), tungsten (W), zinc (Zn), platinum (Pt), titanium (Ti), titanium nitride (TiN), and combinations thereof. The material is free of chromium (Cr) and displays a specular reflectivity such that greater than or equal to about 50% of wavelengths in a visible light range of greater than or equal to about 390 nm to less than or equal to about 750 nm are reflected by the material without scattering.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIGS. 1A-1B. FIG. 1A shows a material having a chrome-like appearance that is free of any chromium (Cr) including a multilayer stack prepared in accordance with certain aspects of the present disclosure. FIG. 1B shows an alternative material having a chrome-like appearance that is free of any chromium (Cr) like that in FIG. 1A, but further including a protective coating layer on the outermost surface of the material to protect the underlying multilayer stack in accordance with certain aspects of the present disclosure.

FIGS. 2A-2D show design material having a chrome-like appearance that is free of any chromium (Cr) including a multilayer stack prepared in accordance with certain aspects of the present disclosure as a Cr-replacement. FIG. 2A shows on the left a schematic with a normal reflection diagram of a Cr-coated object, and on the right a schematic shows an N-layer thin film stack on a glass substrate which is used to mimic the reflection of Cr spectrum while excluding Cr from the material selection in accordance with the present disclosure. FIG. 2B shows the reflection spectrum and visual appearance of a 50 nm thick Cr layer. FIG. 2C shows a sequential design diagram of OML-PPO algorithms. Starting from the first layer, the algorithm outputs the material selection and the corresponding thickness at each layer. The generation process will stop either when the EOS is selected as the material, or the designed stack reaches the maximum number of layers L (here, L=5 is selected). FIG. 2D show a database used by the RL algorithm to select materials for each layer.

FIGS. 3A-3D. FIG. 3A shows a first multilayer Structure 1 (S1) prepared in accordance with certain aspects of the present disclosure as shown in an inset (bottom left)—where the diagram represents a four-layer stack as a replacement for Cr having the following layers: 19 nm Ge/17 nm TiO₂/82 nm SiO₂/139 nm Ni on a glass substrate.

FIG. 3B shows a second multilayer Structure 2 (S2) prepared in accordance with certain aspects of the present disclosure as shown in an inset (bottom left)—where the diagram represents a three-layer RF transmissive replacement structure involving 21 nm Ge/119 nm SiO₂/33 nm Ge on a glass substrate. The plots in FIGS. 3A and 3B show a comparison of the reflection spectra of 50 nm thick chromium layer (red), the predicted (green) and experimentally deposited (blue) replacement chrome stacks for FIG. 3A—S1 and 3B—S2, respectively. The inset graph in FIG. 3A shows a magnified view of the reflectance spectra in the 60-80% region of S1. The plots on the right show a comparison of the literature Cr color, predicted color, and experimentally obtained color of the replacement stacks plotted on relative CIE 1931 coordinates for FIG. 3C—S1 and FIG. 3D—S2, respectively. The magnified views in FIGS. 3C and 3D show how close the three colors are.

FIGS. 4A-4H show four additional multilayer structures disposed on glass substrates in accordance with certain aspects of the present disclosure designed by RL algorithms. FIGS. 4A, 4C, 4E, and 4G show the structures, while FIGS. 4B, 4D, 4F, and 4H show the simulated reflection spectrum (second row) for the respective structures. The inset figures FIGS. 4B, 4D, 4F, and 4H in the second row show the color impression of chromium (Cr) reflection spectrum and reflection spectrum of designed structure.

FIGS. 5A-5C show robustness of the replacement chrome coated on glass and plastic substrates. FIG. 5A shows a comparison between a commercially coated chromium finish on ABS ‘4×4’ substrates used in automobiles (top) and ABS substrates coated using structure S1 (bottom) prepared in accordance with certain aspects of the present disclosure. FIG. 5B shows a commercial ABS plastic (black) coated with the RF transmissive replacement chrome design structure (S2) prepared in accordance with certain aspects of the present disclosure. FIG. 5C shows a PVD chrome (top), replacement stack S1 prepared in accordance with certain aspects of the present disclosure (middle), and green hue replacement chrome stack S1′ (bottom) coated prepared in accordance with certain aspects of the present disclosure on ABS plastic pieces.

FIGS. 6A-6B show angular views of chromium-replacement coatings (multilayer materials) prepared in accordance with certain aspects of the present disclosure. FIG. 6A shows samples with angled views (0° to 50°) of a “Logo” and “X×Y” indicia. They include a conventional chromium-containing (“real”) chrome (top), a multilayer Structure 1 (S1) prepared in accordance with certain aspects of the present disclosure (middle), and another multilayer Structure 2 (S2) prepared in accordance with certain aspects of the present disclosure (bottom) on ABS substrates, showing that the chromium appearance can be maintained over a wide viewing range. FIG. 6B shows simulations showing robustness in the reflection spectrum of S1 (center) and S2 (right) on glass substrates (left) at different incident angles.

FIGS. 7A-7D. Radiofrequency (RF) transmission and reflection measurements in a range of 8 GHz-12 GHz frequencies are shown. The transmission and reflection of a multilayer Structure 2 (S2) prepared in accordance with certain aspects of the present disclosure on 2.6 mm white ABS plastic substrate is shown in FIG. 7A and on 3 mm black ABS plastic in FIG. 7B. As a comparison, for each substrate, the transmission and reflection of a pristine substrate, a 53 nm thick Ge layer on the substrate and S2 coated substrate are all measured and the transmission is found to remain the same. In FIG. 7C, a measurement setup is shown with the waveguide and ports labelled. In FIG. 7D, a waveguide cross section into which the samples were handcrafted to fit is shown.

FIGS. 8A-8F. Performance of a first multilayer Structure 1 (S1) prepared in accordance with certain aspects of the present disclosure is shown in FIG. 8A and a second multilayer Structure 2 (S2) prepared in accordance with certain aspects of the present disclosure are measured. FIG. 8A shows an electric field distribution of the first multilayer Structure 1 (S1), while FIG. 8D shows an electric field distribution for the second multilayer Structure 2 (S2). The strong electric field in air over the whole visible range indicates the structure has a flat spectrum with high reflection. FIGS. 8B and 8E show the step-by-step reflection analysis for S1 and S2 as the multilayer materials are formed, respectively. FIGS. 8C and 8F show the net phase shift at each layer for S1 and S2, respectively. All the reflection components have an approximate 2π net phase shift, leading to constructive interference and an overall increase in the reflection compared to a single Ge layer.

FIGS. 9A-9D show general design principles for forming a chrome-like material according to certain aspects of the present disclosure. FIG. 9A shows reflection for metal color having chromium (Cr), while FIG. 9B shows a gold-based color provided by reinforcement learning (RL) techniques. The red, green and blue dashed lines refer to the reflection of top layer of metal, semiconductor and dielectric materials. The inset color brick shows the Cr and Au color impression respectively. FIGS. 9C and 9D show different structures formed in accordance with certain aspects of the present disclosure.

Corresponding reference numerals indicate corresponding parts throughout the several views of the drawings.

### DETAILED DESCRIPTION

Example embodiments are provided so that this disclosure will be thorough, and will fully convey the scope to those who are skilled in the art. Numerous specific details are set forth such as examples of specific compositions, components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, elements, compositions, steps, integers, operations, and/or components, but do not preclude the presence or addition of one or more other features, integers, steps, operations, elements, components, and/or groups thereof. Although the open-ended term “comprising,” is to be understood as a non-restrictive term used to describe and claim various embodiments set forth herein, in certain aspects, the term may alternatively be understood to instead be a more limiting and restrictive term, such as “consisting of” or “consisting essentially of.” Thus, for any given embodiment reciting compositions, materials, components, elements, features, integers, operations, and/or process steps, the present disclosure also specifically includes embodiments consisting of, or consisting essentially of, such recited compositions, materials, components, elements, features, integers, operations, and/or process steps. In the case of “consisting of,” the alternative embodiment excludes any additional compositions, materials, components, elements, features, integers, operations, and/or process steps, while in the case of “consisting essentially of,” any additional compositions, materials, components, elements, features, integers, operations, and/or process steps that materially affect the basic and novel characteristics are excluded from such an embodiment, but any compositions, materials, components, elements, features, integers, operations, and/or process steps that do not materially affect the basic and novel characteristics can be included in the embodiment.

Any method steps, processes, and operations described herein are not to be construed as necessarily requiring their performance in the particular order discussed or illustrated, unless specifically identified as an order of performance. It is also to be understood that additional or alternative steps may be employed, unless otherwise indicated.

When a component, element, or layer is referred to as being “on,” “engaged to,” “connected to,” or “coupled to” another element or layer, it may be directly on, engaged, connected or coupled to the other component, element, or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various steps, elements, components, regions, layers and/or sections, these steps, elements, components, regions, layers and/or sections should not be limited by these terms, unless otherwise indicated. These terms may be only used to distinguish one step, element, component, region, layer or section from another step, element, component, region, layer or section. Terms such as “first,” “second,” and other numerical terms when used herein do not imply a sequence or order unless clearly indicated by the context. Thus, a first step, element, component, region, layer or section discussed below could be termed a second step, element, component, region, layer or section without departing from the teachings of the example embodiments.

Spatially or temporally relative terms, such as “before,” “after,” “inner,” “outer,” “beneath,” “below,” “lower,” “above,” “upper,” and the like, may be used herein for ease of description to describe one element or feature's relationship to another element(s) or feature(s) as illustrated in the figures. Spatially or temporally relative terms may be intended to encompass different orientations of the device or system in use or operation in addition to the orientation depicted in the figures.

Throughout this disclosure, the numerical values represent approximate measures or limits to ranges to encompass minor deviations from the given values and embodiments having about the value mentioned as well as those having exactly the value mentioned. Other than in the working examples provided at the end of the detailed description, all numerical values of parameters (e.g., of quantities or conditions) in this specification, including the appended claims, are to be understood as being modified in all instances by the term “about” whether or not “about” actually appears before the numerical value. “About” indicates that the stated numerical value allows some slight imprecision (with some approach to exactness in the value; approximately or reasonably close to the value; nearly). If the imprecision provided by “about” is not otherwise understood in the art with this ordinary meaning, then “about” as used herein indicates at least variations that may arise from ordinary methods of measuring and using such parameters. For example, “about” may comprise a variation of less than or equal to 5%, optionally less than or equal to 4%, optionally less than or equal to 3%, optionally less than or equal to 2%, optionally less than or equal to 1%, optionally less than or equal to 0.5%, and in certain aspects, optionally less than or equal to 0.1%.

In addition, disclosure of ranges includes disclosure of all values and further divided ranges within the entire range, including endpoints and sub-ranges given for the ranges.

Example embodiments will now be described more fully with reference to the accompanying drawings.

In various aspects, the present disclosure provides a material having a chrome-like appearance that is free of chromium and thus environmentally friendly. The material may comprise a multilayer thin film stack that can mimic the visual appearance of chromium-plated (e.g., hexavalent chromium (Cr(VI))) objects but omit use of any chromium metal. In certain variations, the thin films in the multilayer stack may be formed via physical vapor deposition (PVD). In alternative variations, if chrome metal is desired, the multilayer stack may easily incorporate a thin chrome layer therein. Certain variations of the material are further designed to be transmissive in the radio frequency (RF) electromagnetic radiation spectrum, while retaining the metallic appearance of chromium. In this manner, decorative chrome-like materials of the present disclosure enable the use in RF applications that were not previously possible. The present teachings thus provide an environmentally sustainable approach to produce attractive metallic-looking coatings.

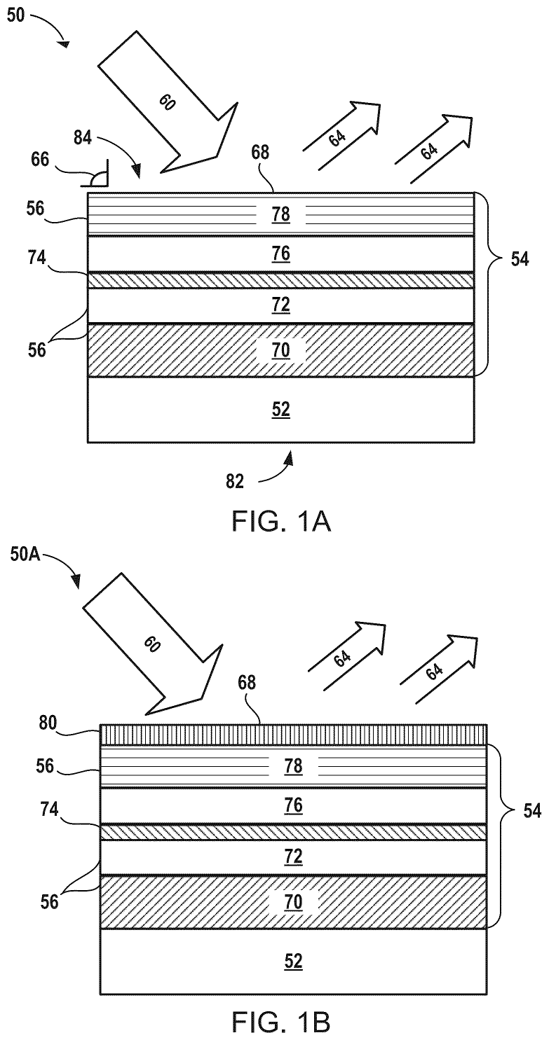

In various aspects, the present disclosure provides a material structure 50 having a chrome-like appearance, for example as shown in FIG. 1A, but advantageously being free of any chromium (Cr). The chrome-like material structure 50 that comprises a substrate 52 and a multilayer stack 54 disposed on the substrate that comprises at least three material layers 56. As shown in FIG. 1, an electromagnetic wave 60, such as sunlight or ambient light, is directed towards the chrome-like material 50. In various aspects, the chrome-like material 50 is capable of reflecting a portion of the electromagnetic spectrum/electromagnetic wave 60 having a range of predetermined wavelengths to generate a reflected output 64 that displays minimal angle dependence with respect to an incidence or viewing angle 66 from which the chrome-like material 50 may be viewed or observed (e.g., by a human or machine). As shown in FIG. 1A, the viewing angle 66 is 90° (meaning the view is perpendicular to the surface) but may vary based on the position of observation to be anywhere from greater than 0° to less than 180° (e.g., ±90°). Notably, the reflected output 64 occurs at the same incident angle on an opposite side to the electromagnetic wave 60 with respect to a surface 68 of the chrome-like material 50 thus exhibiting specular reflection, rather than any scattering occurring that would occur with diffusive reflection.

In various aspects, the layers 56 may be thin film layers, for example, having a maximum average thickness of less than or equal to about 300 nm, optionally less than or equal to about 275 nm, optionally less than or equal to about 250 nm, optionally less than or equal to about 225 nm, optionally less than or equal to about 200 nm, optionally less than or equal to about 175 nm. In certain variations, each layer 56 of the stack 54 may have a maximum average thickness of less than or equal to about 150 nm. In certain variations, each layer 56 may respectively have an average thickness of greater than or equal to about 15 nm to less than or equal to about 150 nm. At least two material layers 56 in the multilayer stack 54 are compositionally distinct from one another. If in certain variations, a bottom or lowest reflector layer needs to be thicker, it can assume arbitrary thickness according to specific requirements, but will this not affect the overall chrome-appearance of the entire multilayer stack.

As will be described further below, each material layer of the multilayer stack independently is selected to include a composition selected from a first composition of an optically transparent dielectric material, a second composition of a light absorbing material (e.g., a semiconductor), and a third composition of a light reflecting material, such as a metal, as detailed herein. In preferred aspects, the material is free of chromium (Cr); however, exhibits a chrome-like appearance. In alternative aspects, the multilayer stack may include a material layer that comprises a fourth composition comprising chromium (Cr).

A “chrome-like” appearance may be defined by the material displaying a specular reflectivity, meaning that the reflection is mirror-like so that the reflected output of light which arrives from a given direction reflects at the same angle on an opposing side of a surface without scattering (in contrast to diffuse reflection where light reflects from a surface in a broad range of directions). In certain aspects, the specular reflectivity of the chrome-like material provided by the present disclosure may have a reflectivity such that greater than or equal to about 50% of visible light (e.g., all wavelengths of greater than or equal to about 390 nm to less than or equal to about 750 nm), optionally greater than or equal to about 60%, and in certain variations optionally greater than or equal to about 70% of the visible light is reflected by the material without scattering.

In certain aspects, light reflected from the material exhibits a peak range of wavelengths corresponding to a hue or desired color. Thus, the material has a chrome-like appearance but with varied degree of color hues. In terms of spectrum, the target reflection spectrum may deviate from an ideal chrome spectrum by including a certain peak feature superposed on top of the relatively flat chrome spectrum. Such a peak corresponding to a desired color can be accomplished by adjusting a thickness of layers in the multilayer stack where materials are otherwise chosen to produce the ideal chrome appearance with neutral color.

As noted above, finding materials that mimic the appearance of chromium to human eye, yet are free of chromium has been a challenge. However, a new reinforcement learning (RL)-based design approach has been used to generate thin multilayer structures with a target optical property, namely a chrome-like appearance. These novel designed structures generated by this new RL algorithm can mimic and replace decorative chrome coatings that are widely used in industry and everyday life, but are manufactured without requiring a highly hazardous chemical process. RL outperforms conventional optimization techniques and can consider a large number of materials while designing the thickness simultaneously due to the deep learning-based sequence modeling technique. To provide sustainable materials and devices, a database of materials that are environmentally friendly and easily manufacturable are used for the algorithm. The present disclosure thus provides new environmentally friendly and multi-functional thin film stacks that mimic the color and appearance of chrome-finished surfaces, by using such a RL learning algorithm. The designed structures may be fabricated using physical vapor deposition (PVD) and have been validated experimentally through reflection spectra measurements.

Additionally, in accordance with certain aspects of the present disclosure, the application of decorative chrome-like coatings and materials has been expanded into applications with long-range communication, like radiofrequency (RF) electromagnetic radiation. Such materials having a chrome-like appears are free of any metals and thus permit radiofrequency waves to transmit therethrough. In certain aspects, a material that is transparent to radiofrequency (RF) electromagnetic radiation permits greater than or equal to about 60% of wavelengths of greater than or equal to about 1 mm to less than or equal to about 10 m to transmit therethrough.

Any known substrate 52 can be used for the chrome-like material 50. In certain aspects, the substrate 52 may be selected to be transmissive to visible light, radiofrequency electromagnetic waves, or other ranges of wavelengths. Transmissivity for the substrate 52 may include transparency or semi-transparency and thus be defined to be greater than or equal to about 40% of a target or predetermined range of wavelengths of electromagnetic energy, optionally greater than or equal to about 45%, optionally greater than or equal to about 50%, optionally greater than or equal to about 55%, optionally greater than or equal to about 60%, optionally of greater than or equal to about 65%, optionally greater than or equal to about 70%, optionally greater than or equal to about 75%, optionally greater than or equal to about 80%, optionally greater than or equal to about 85%, optionally greater than or equal to about 90%, and in certain aspects, optionally greater than or equal to about 95% of the electromagnetic energy at the predetermined range of wavelengths (e.g., in the visible or radiofrequency ranges of the spectrum) is transmitted. When the substrate 52 is transparent, it is possible that the film layers in 50 can use fewer layers than five (5) to achieve the chrome appearance.

In certain aspects, the substrate 52 may be semi-transmissive or transmissive for visible light, for example, permitting a predetermined range of wavelengths of visible light to pass through. Such a variation may be suitable where a backlit surface is used, such that the multilayer stack 54 is reflective during certain conditions (e.g., during day when daylight is present), while the surface may be backlight during other conditions (e.g., nighttime) to provide lighting beneath the substrate 54 (for example, in an interior compartment of a car).

In other aspects, the substrate 52 may be reflective or treated to be reflective (e.g., with a reflective metal coating layer, as further described herein), meaning a significant portion of a predetermined range of wavelengths of electromagnetic energy, for example, in the visible light range is reflected. Thus, in certain aspects, the substrate 52 may reflect greater than or equal to about 60% of electromagnetic energy at the predetermined range of wavelengths, optionally of greater than or equal to about 65%, optionally greater than or equal to about 70%, optionally greater than or equal to about 75%, optionally greater than or equal to about 80%, optionally greater than or equal to about 85%, optionally greater than or equal to about 90%, and in certain preferred aspects, optionally greater than or equal to about 95% of the electromagnetic energy at the predetermined range of wavelengths (e.g., in the visible range of the spectrum). In these cases, the film layers in 50 can be modified and use even few layers to achieve the chrome appearance.

Suitable examples of substrates 52 include an inorganic dielectric material, such as a glass-based substrate, a metal, or a polymer. For example, a suitable polymeric substrate optionally comprises polyesters, such as polyethylene terephthalate (PET), polyethylene naphthalate or (poly(ethylene 2,6-naphthalate) (PEN), polycarbonates, polyacrylates and polymethacrylates, including poly(methylmethacrylate) (PMMA), poly(methacrylate), poly(ethylacrylate), siloxanes, like polydimethylsiloxane (PDMS), acrylonitrile butadiene styrene (ABS), other polished plastics, wood, and the like. In other variations, the substrate 52 may comprise silicon dioxide, silicon, and the like, by way of non-limiting example.

In various aspects, the multilayer stack 54 disposed on the substrate 52 comprises at least three material layers 56. Each material layer of the multilayer stack independently is selected to include a composition that may include a first composition, a second composition, or a third composition. The first composition comprises an optically transparent dielectric material selected from the group consisting of: titanium oxide (TiO₂), silicon dioxide (SiO₂), magnesium fluoride (MgF₂), magnesium oxide (MgO), aluminum oxide (Al₂O₃), hafnium oxide (HfO₂), zirconium dioxide (ZrO₂), zinc sulfide (ZnS), zinc selenide (ZnSe), zinc oxide (ZnO), silicon nitride (Si₃N₄), silicon dioxide (SiO₂), tin oxide (SnO₂), and combinations thereof. The second composition comprises a light absorbing material. In certain variations, the light absorbing material may comprise an element selected from the group consisting of elements from Groups 2 to 16, for example, Groups 2 and 13 to 16, or Groups 13 to 16, of the IUPAC Periodic Table. As referred to herein, “Group” refers to the Group numbers (i.e., columns) of the Periodic Table as defined in the current IUPAC Periodic Table, also known as Groups II to VI. Thus, in certain variations, the light absorbing material may include an element selected from Groups 2 and 13 to 16, or more particularly, Groups 13 to 16, for example, semiconductors and compounds thereof selected from Periodic Table Groups III to V (IUPAC Groups 13 to 15) of, including Group IV (IUPAC Group 14), such as silicon (Si), germanium (Ge), silicon carbide (SiC), Groups III to V (IUPAC Groups 13 to 15) semiconductor compounds, such as gallium nitride (GaN), gallium phosphide (GaP), Groups II to VI (IUPAC Groups 2 to 16) semiconductor compounds, such as zinc sulfide (ZnS), zinc selenide (ZnSe), other chalcogenides, iron oxides, and combinations thereof. Chalcogenides may include an element from Group VI (IUPAC Group 16) of the Periodic Table, including various sulfides, selenides, tellurides, and the like. In certain variations, the second composition comprises a light absorbing material selected from the group consisting of: silicon (Si), germanium (Ge), silicon carbide (SiC), gallium nitride (GaN), gallium phosphide (GaP), zinc sulfide (ZnS), zinc selenide (ZnSe), chalcogenides, iron oxides, and combinations thereof. The third composition comprises a light reflecting material selected from the group consisting of: nickel (Ni), aluminum (Al), copper (Cu), silver (Ag), gold (Au), tungsten (W), zinc (Zn), platinum (Pt), titanium (Ti), titanium nitride (TiN), and combinations thereof.

In accordance with certain aspects of the present disclosure, each material is free of chromium (Cr). However, the multilayer stack 54 formed by the at least three material layers 56 displays a specular reflectivity, for example, as defined above to be greater than or equal to about 50% of wavelengths, optionally greater than or equal to about 60%, and in certain aspects, greater than or equal to about 70% in a visible light range of greater than or equal to about 390 nm to less than or equal to about 750 nm are reflected by the material without scattering.

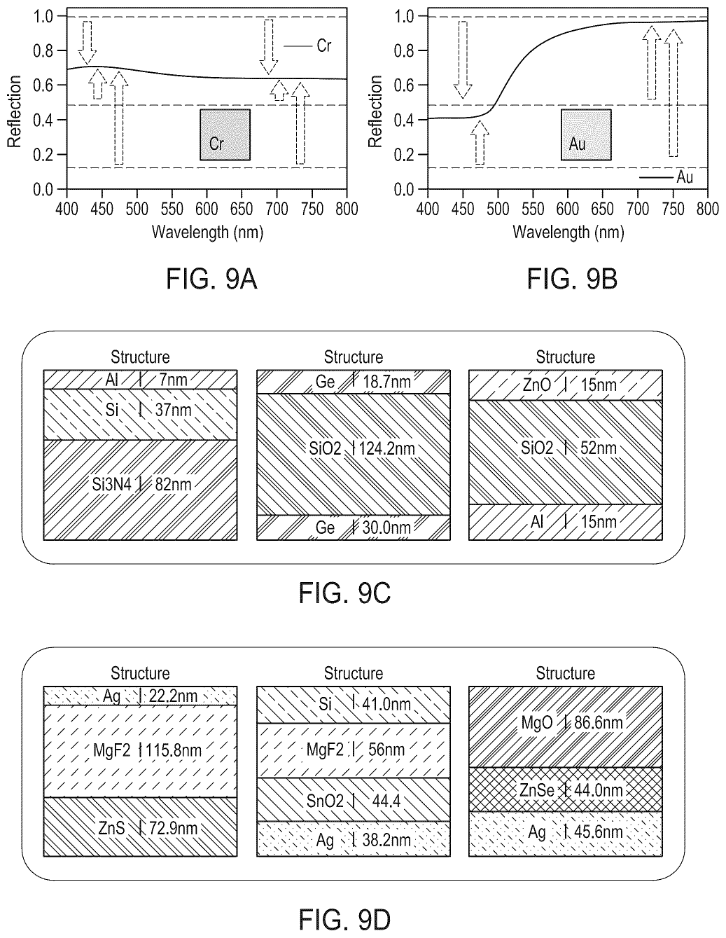

In certain aspects, one design of the multilayer stack 54 may proceed as follows. The multilayer stack 54 defines a first side 82 adjacent to the substrate 52 and a second side 84 opposite to the first side 82 defining a terminal material layer (shown as fifth layer 78 in FIG. 1A). In this design, the terminal material layer comprises the third composition comprising the light reflecting material (e.g., a reflective metal). By way of further explanation, where the top layer of the multilayer stack is metal (e.g., Al or Ag), the reflection R=|r₀₁|² will be high enough and close to 100% (as shown by a red dashed line in FIGS. 9A and 9B. Extra layers are added below the terminal material layer comprising the light reflecting material in order to provide destructive interference to bring down the specific spectrum to target spectrum (shown as red arrows).

Thus, in such variations, the multilayer stack 54 may further comprise one or more intermediate material layers comprising the first composition comprising the optically transparent dielectric material disposed between the terminal material layer and the substrate 52. In certain other variations the multilayer stack 54 may further comprise at least one second intermediate material layer disposed between the substrate and the terminal material layer that comprises the second composition comprising the light absorbing material disposed between the terminal material layer and the substrate. By way of non-limiting example, for such variations, the multilayer stack comprises one of the following.

In one variation, the multilayer stack 54 comprises at least three layers 56. In certain variations, the multilayer stack 54 may comprise between three and five active layers 56, including embodiments with a three active layer stack, a four active layer stack, and a five active layer stack. This includes a first layer 70 disposed on the substrate 52. The first layer 70 may be considered to be a reflective layer in certain variations. The first layer 70 may comprise one of the first, second, or third compositions. In certain variations, the first layer 70 may comprise a first composition selected from the group consisting of: nickel (Ni), zinc (Zn), germanium (Ge), gold (Au), aluminum oxide (Al₂O₃), aluminum (Al), and combinations thereof. A second layer 72 is disposed over the first layer 70. The second layer 72 may comprise one of the first, second, or third compositions. In certain variations, the second layer 72 may comprise a second composition selected from the group consisting of: silicon dioxide (SiO₂), aluminum (Al), aluminum oxide (Al₂O₃), magnesium fluoride (MgF₂), magnesium oxide (MgO), and combinations thereof.

A third layer 74 is disposed over the second layer 72. A third layer 74 may comprise one of the first, second, or third compositions. In certain variations, the third layer 74 may be considered to be an absorber layer. The third layer 74 may comprise a third composition selected from the group consisting of: germanium (Ge), tungsten (W), zinc (Zn), silver (Ag), aluminum (Al), titanium dioxide (TiO₂), magnesium fluoride (MgF₂), silicon dioxide (SiO₂), and combinations thereof. In certain variations, the multilayer stack may further comprise an optional fourth layer 76. Again. The fourth layer 76 may comprise a composition selected from one of the first, second, or third compositions. The optional fourth layer 76 may in certain variations, comprise a second absorber layer. In other variations, the fourth layer 76 may be considered to be a top layer of the multilayer stack 54, which may serve as an antireflective layer, for example. Thus, in one variation, the fourth layer 76 comprises a fourth material selected from the group consisting of: germanium (Ge), silicon dioxide (SiO₂), aluminum oxide (Al₂O₃), hafnium oxide (HfO₂), tungsten (W), zinc (Zn), silver (Ag), aluminum (Al), magnesium fluoride (MgF₂), and combinations thereof.

Where the multilayer stack 54 comprises at least five layers, a fifth layer 78 may be the terminal or top final active layer of the stack. In such variations, the fourth layer 76 may serve as an absorber layer where the fourth material is selected from the group consisting of: tungsten (W), zinc (Zn), silver (Ag), and combinations thereof. The fifth layer 78 may be an antireflective layer that comprises a fifth material selected from the group consisting of: germanium (Ge), silicon dioxide (SiO₂), hafnium oxide (HfO₂), and combinations thereof.

It should be noted that while in certain variations, each layer may be directly adjacent to and in contact with the layer described as being below, while in other variations, additional layers or coatings may be disposed between such layers.

In further variations, each material layer 56 comprises a composition or material independently selected from the group consisting of: germanium (Ge), titanium oxide (TiO₂), silicon dioxide (SiO₂), nickel (Ni), aluminum (Al), aluminum oxide (Al₂O₃), silver (Ag), magnesium fluoride (MgF₂), magnesium oxide (MgO), silicon (Si), silicon (Si), zinc sulfide (ZnS), zinc selenide (ZnSe), and combinations thereof.

In yet further variations, each material layer 56 comprises a composition or material is independently selected from the group consisting of: germanium (Ge), titanium oxide (TiO₂), silicon dioxide (SiO₂), nickel (Ni), and combinations thereof.

In one variation, the multilayer stack 54 may have four distinct material layers, where a first material layer adjacent to the substrate comprises aluminum oxide (Al₂O₃), a second material layer comprises magnesium oxide (MgO), a third material layer comprises titanium dioxide (TiO₂), and the terminal material layer comprises aluminum (Al). In another variation, the multilayer stack comprises three distinct material layers, where a first material layer adjacent to the substrate comprises silicon nitride (Si₃N₄), a second material layer comprises silicon (Si), and the terminal material layer comprises aluminum (Al). In yet another variation, the multilayer stack comprises three distinct material layers, where a first material layer adjacent to the substrate comprises zinc sulfide (ZnS), a second material layer comprises magnesium fluoride (Mg₂F), and the terminal material layer comprises silver (Ag).

In certain aspects, another design of the multilayer stack 54 may proceed as follows. In this design, the terminal material layer on the second side 84 of the multilayer stack 54 comprises the second composition comprising the light absorbing material (e.g., a semiconductor). By way of further explanation, if the top layer is a semiconductor material (Si or Ge), it will have intermediate reflection, and R=|r₀₁|² will be will be close to 40-50% (shown as green dashed line in FIGS. 9A and 9B). Extra layers can then be added between the substrate and terminal layer of the multilayer stack 54 to provide slightly constructive interference to improve the specific spectrum to target spectrum (shown as green arrows). The multilayer stack may thus further comprise one or more intermediate material layers comprising the first composition comprising the optically transparent dielectric material disposed between the terminal material layer formed of the second composition and the substrate 52. In other variations, the multilayer stack 54 may have at least one intermediate material layer disposed between the terminal material layer and the substrate that also comprises the second composition comprising the light absorbing material (which may be the same or different light absorbing material as the top or terminal layer). In other aspects, the first side of the multilayer stack comprises a bottom material layer adjacent to the substrate that comprises the third composition comprising the light reflecting material.

In one variation of such a design, the multilayer stack 54 has three layers. A first material layer adjacent to the substrate comprises germanium (Ge), a second material layer comprises silicon dioxide (SiO₂), and the terminal material layer comprises germanium (Ge). In another variation, the multilayer stack 54 has four distinct material layers. A first material layer is adjacent to the substrate that comprises nickel (Ni), a second material layer comprises silicon dioxide (SiO₂), a third material layer comprises titanium dioxide (TiO₂), and the terminal material layer comprises germanium (Ge). Yet another variation of the multilayer stack 54 may include four distinct material layers, where a first material layer adjacent to the substrate comprises silver (Ag), a second material layer comprises tin oxide (SnO₂), a third material layer comprises magnesium fluoride (MgF₂), and the terminal material layer comprises silicon (Si).

In certain aspects, yet another design of the multilayer stack 54 may proceed as follows. In this design, the terminal material layer on the second side 84 of the multilayer stack 54 comprises the first composition comprising the optically transparent dielectric material. By way of further explanation, if the top layer is a dielectric material, it will have low reflection, and R=|r⁰¹|² will be close to 10-20% (shown as blue dashed line in FIGS. 9A-9B). Extra layers will be added beneath it in the multilayer stack in order to provide constructive interference to strongly improve the specific spectrum to target spectrum (shown as blue arrows). In certain variations, an extra metal layer to increase reflection. Thus, in certain variations, the bottom material layer adjacent to the substrate 52 comprises the third composition comprising the light reflecting material. In certain aspects, the multilayer stack 54 further comprises at least one intermediate material layer disposed between the bottom material layer and the terminal material layer comprising the first composition comprising the optically transparent dielectric material. In other variations, the multilayer stack 54 further comprises at least one intermediate material layer comprising the second composition comprising the light absorbing material.

In one variation, the multilayer stack 54 formed by such a design principle may comprise one of the following embodiments. The multilayer stack 54 may comprise three distinct material layers. A first material layer adjacent to the substrate comprises germanium (Ge), a second material layer comprises aluminum (Al), and the terminal or uppermost material layer comprises magnesium fluoride (MgF₂). In another variation with three distinct material layers, a first material layer adjacent to the substrate comprises aluminum (Al), a second material layer comprises silicon dioxide (SiO₂), and the terminal material layer comprises zinc oxide (ZnO). In yet another variation, the three-layer multilayer stack comprises a first material layer adjacent to the substrate comprises silver (Ag), a second material layer comprises zinc selenide (ZnSe), and the terminal or top material layer comprises zinc oxide (ZnO).

In other variations, the multilayer stack 54 has four distinct material layers. A first material layer adjacent to the substrate comprises aluminum (Al), a second material layer comprises aluminum oxide (Al₂O₃), a third material layer comprises aluminum (Al), and the terminal material layer comprises aluminum oxide (Al₂O₃). In other embodiments, the multilayer stack 54 has five distinct material layers. A first material layer adjacent to the substrate comprises aluminum oxide (Al₂O₃), a second material layer comprises aluminum (Al), a third material layer comprises silicon dioxide (SiO₂), a fourth material layer comprises magnesium fluoride (MgF₂), and the terminal material layer comprises silicon dioxide (SiO₂).

In another embodiment, a first material layer adjacent to the substrate comprises gold (Au), a second material layer comprises magnesium fluoride (MgF₂), a third material layer comprises germanium (Ge), a fourth material layer comprises zinc (Zn), and the terminal material layer comprises hafnium oxide (HfO₂).

In yet another embodiment, a first material layer adjacent to the substrate comprises gold (Au), a second material layer comprises aluminum oxide (Al₂O₃), a third material layer comprises germanium (Ge), a fourth material layer comprises zinc (Zn), and the terminal material layer comprises hafnium oxide (HfO₂).

In a further embodiment, a first layer adjacent to the substrate comprises gold (Au), a second material layer comprises silicon dioxide (SiO₂), a third material layer comprises germanium (Ge), a fourth material layer comprises silver (Ag), and the terminal material layer comprises silicon dioxide (SiO₂).

In one embodiment, a first material layer adjacent to the substrate comprises nickel (Ni), a second material layer comprises aluminum oxide (Al₂O₃), a third material layer comprises germanium (Ge), a fourth material layer comprises zinc (Zn), and the terminal material layer comprises hafnium oxide (HfO₂).

In another embodiment, a first material layer adjacent to the substrate comprises zinc (Zn), a second material layer comprises silicon dioxide (SiO₂), a third material layer comprises germanium (Ge), a fourth material layer comprises tungsten (W), and the terminal material layer comprises hafnium oxide (HfO₂).

In a further embodiment, a first layer adjacent to the substrate comprises aluminum oxide (Al₂O₃), a second layer comprises aluminum (Al), a third layer comprises silicon dioxide (SiO₂), a fourth layer comprises magnesium fluoride (MgF₂), and the terminal material layer comprises silicon dioxide (SiO₂).

In another embodiment, a first layer adjacent to the substrate comprises gold (Au), a second layer comprises magnesium fluoride (MgF₂), a third layer comprises germanium (Ge), a fourth layer comprises zinc (Zn), and the terminal material layer comprises hafnium oxide (HfO₂).

In still another embodiment, a first layer adjacent to the substrate comprises gold (Au), a second layer comprises aluminum oxide (Al₂O₃), a third layer comprises germanium (Ge), a fourth layer comprises zinc (Zn), and the terminal material layer comprises hafnium oxide (HfO₂).

In one embodiment, a first layer adjacent to the substrate comprises gold (Au), a second layer comprises silicon dioxide (SiO₂), a third layer comprises germanium (Ge), a fourth layer comprises silver (Ag), and the terminal material layer comprises silicon dioxide (SiO₂).

In another embodiment, a first layer adjacent to the substrate comprises nickel (Ni), a second layer comprises aluminum oxide (Al₂O₃), a third layer comprises germanium (Ge), a fourth layer comprises zinc (Zn), and the terminal material layer comprises hafnium oxide (HfO₂).

In yet another embodiment, a first layer adjacent to the substrate comprises zinc (Zn), a second layer comprises silicon dioxide (SiO₂), a third layer comprises germanium (Ge), a fourth layer comprises tungsten (W), and the terminal material layer comprises hafnium oxide (HfO₂).

As will be described further below, in certain embodiments, the multilayer stack 54 is free of any metals. In certain aspects, each material layer 56 is independently selected from the group consisting of: germanium (Ge), silicon (Si), titanium oxide (TiO₂), silicon dioxide (SiO₂), and combinations thereof.

In one particular variation, the multilayer stack 54 forming the chrome-like material comprises three active layers 56 over substrate 52. A first layer 70 is adjacent to the substrate 52 and comprises germanium (Ge). The first layer 70 may have a first average thickness of greater than or equal to about 18 nm to less than or equal to about 23 nm, for example, about 20 nm. A second layer 72 is disposed over the first layer 70 and comprises aluminum (Al). The second layer 72 may have a second average thickness of greater than or equal to about 18 nm to less than or equal to about 23 nm, for example, about 20 nm. A third layer 74 is disposed over the second layer 72 and comprises magnesium fluoride (MgF₂). A third average thickness of the third layer 74 may be greater than or equal to about 87 nm to less than or equal to about 92 nm, for example, about 90 nm.

In another variation, the multilayer stack 54 forming the chrome-like material comprises four active layers 56 over substrate 52. A first layer 70 is adjacent to the substrate 52 and comprises nickel (Ni). The first layer 70 may have a first average thickness of greater than or equal to about 137 nm to less than or equal to about 142 nm, for example, about 139 nm. A second layer 72 is disposed over the first layer 70 and comprises silicon dioxide (SiO₂). The second layer 72 may have a second average thickness of greater than or equal to about 80 nm to less than or equal to about 85 nm, for example, about 82 nm. A third layer 74 is disposed over the second layer 72 and comprises titanium oxide (TiO₂). A third average thickness of the third layer 74 may be greater than or equal to about 15 nm to less than or equal to about 20 nm, for example, about 17 nm. Finally, a fourth layer 76 is disposed over the third layer 74 and comprises germanium (Ge). The fourth layer 76 may have a fourth average thickness of greater than or equal to about 17 nm to less than or equal to about 22 nm, for example, about 19 nm.

In another variation, the multilayer stack 54 forming the chrome-like material comprises four active layers 56 over substrate 52. A first layer 70 is adjacent to the substrate 52 and comprises aluminum oxide (Al₂O₃). The first layer 70 may have a first average thickness of greater than or equal to about 138 nm to less than or equal to about 143 nm, for example, about 140 nm. A second layer 72 is disposed over the first layer 70 and comprises magnesium oxide (MgO). The second layer 72 may have a second average thickness of greater than or equal to about 10 nm to less than or equal to about 15 nm, for example, about 12 nm. A third layer 74 is disposed over the second layer 72 and comprises titanium oxide (TiO₂). A third average thickness of the third layer 74 may be greater than or equal to about 52 nm to less than or equal to about 57 nm, for example, about 55 nm. Finally, a fourth layer 76 is disposed over the third layer 74 and comprises aluminum (Al). The fourth layer 76 may have a fourth average thickness of greater than or equal to about 11 nm to less than or equal to about 16 nm, for example, about 14 nm.

In one further variation, the multilayer stack 54 forming the chrome-like material comprises four active layers 56 over substrate 52. A first layer 70 is adjacent to the substrate 52 and comprises aluminum (Al). The first layer 70 may have a first average thickness of greater than or equal to about 20 nm to less than or equal to about 25 nm, for example, about 22 nm. A second layer 72 is disposed over the first layer 70 and comprises aluminum oxide (Al₂O₃). The second layer 72 may have a second average thickness of greater than or equal to about 47 nm to less than or equal to about 52 nm, for example, about 49 nm. A third layer 74 is disposed over the second layer 72 and comprises aluminum (Al). A third average thickness of the third layer 74 may be greater than or equal to about 26 nm to less than or equal to about 31 nm, for example, about 28 nm. Finally, a fourth layer 76 is disposed over the third layer 74 and comprises aluminum oxide (Al₂O₃). The fourth layer 76 may have a fourth average thickness of greater than or equal to about 78 nm to less than or equal to about 83 nm, for example, about 80 nm.

In one variation, the multilayer stack 54 forming the chrome-like material comprises five layers 56 over substrate 52. A first layer 70 is adjacent to the substrate 52 and comprises aluminum oxide (Al₂O₃). The first layer 70 may have a first average thickness of greater than or equal to about 47 nm to less than or equal to about 52 nm, for example, about 50 nm. A second layer 72 is disposed over the first layer 70 and comprises aluminum (Al). The second layer 72 may have a second average thickness of greater than or equal to about 23 nm to less than or equal to about 28 nm, for example, about 25 nm. A third layer 74 is disposed over the second layer 72 and comprises silicon dioxide (SiO₂). A third average thickness of the third layer 74 may be greater than or equal to about 23 nm to less than or equal to about 28 nm, for example, about 25 nm. A fourth layer 76 is disposed over the third layer 74 and comprises magnesium fluoride (MgF₂). The fourth layer 76 may have a fourth average thickness of greater than or equal to about 47 nm to less than or equal to about 52 nm, for example, about 50 nm. A fifth layer 78 is disposed over the fourth layer 76 and comprises silicon dioxide (SiO₂). The fifth layer 78 may have a fifth average thickness of greater than or equal to about 23 nm to less than or equal to about 28 nm, for example, about 25 nm.

In yet another variation, the multilayer stack 54 forming the chrome-like material comprises five layers 56 over substrate 52. A first layer 70 is adjacent to the substrate 52 and comprises gold (Au). The first layer 70 may have a first average thickness of greater than or equal to about 95 nm to less than or equal to about 105 nm, for example, about 100 nm. A second layer 72 is disposed over the first layer 70 and comprises magnesium fluoride (MgF₂). The second layer 72 may have a second average thickness of greater than or equal to about 215 nm to less than or equal to about 255 nm, for example, about 218 nm or alternatively about 249 nm. A third layer 74 is disposed over the second layer 72 and comprises germanium (Ge). A third average thickness of the third layer 74 may be greater than or equal to about 10 nm to less than or equal to about 15 nm, for example, about 11 nm or 12 nm. A fourth layer 76 is disposed over the third layer 74 and comprises zinc (Zn). The fourth layer 76 may have a fourth average thickness of greater than or equal to about 13 nm to less than or equal to about 18 nm, for example, about 15 nm. A fifth layer 78 is disposed over the fourth layer 76 and comprises hafnium oxide (HfO₂). The fifth layer 78 may have a fifth average thickness of greater than or equal to about 90 nm to less than or equal to about 100 nm, for example, about 93 nm or alternatively, about 97 nm.

In another variation, the multilayer stack 54 forming the chrome-like material comprises five layers 56 over substrate 52. A first layer 70 is adjacent to the substrate 52 and comprises gold (Au). The first layer 70 may have a first average thickness of greater than or equal to about 95 nm to less than or equal to about 105 nm, for example, about 100 nm. A second layer 72 is disposed over the first layer 70 and comprises aluminum oxide (Al₂O₃). The second layer 72 may have a second average thickness of greater than or equal to about 200 nm to less than or equal to about 210 nm, for example, about 202 nm or alternatively about 207 nm. A third layer 74 is disposed over the second layer 72 and comprises germanium (Ge). A third average thickness of the third layer 74 may be greater than or equal to about 13 nm to less than or equal to about 18 nm, for example, about 15 nm. A fourth layer 76 is disposed over the third layer 74 and comprises zinc (Zn). The fourth layer 76 may have a fourth average thickness of greater than or equal to about 11 nm to less than or equal to about 16 nm, for example, about 14 nm. A fifth layer 78 is disposed over the fourth layer 76 and comprises hafnium oxide (HfO₂). The fifth layer 78 may have a fifth average thickness of greater than or equal to about 5 nm to less than or equal to about 65 nm, for example, about 5 nm or alternatively, about 61 nm.

In yet a further variation, the multilayer stack 54 forming the chrome-like material comprises five layers 56 over substrate 52. A first layer 70 is adjacent to the substrate 52 and comprises gold (Au). The first layer 70 may have a first average thickness of greater than or equal to about 95 nm to less than or equal to about 105 nm, for example, about 100 nm. A second layer 72 is disposed over the first layer 70 and comprises silicon dioxide (SiO₂). The second layer 72 may have a second average thickness of greater than or equal to about 125 nm to less than or equal to about 150 nm, for example, about 130 nm or alternatively about 147 nm. A third layer 74 is disposed over the second layer 72 and comprises germanium (Ge). A third average thickness of the third layer 74 may be greater than or equal to about 13 nm to less than or equal to about 18 nm, for example, about 15 nm. A fourth layer 76 is disposed over the third layer 74 and comprises silver (Ag). The fourth layer 76 may have a fourth average thickness of greater than or equal to about 10 nm to less than or equal to about 15 nm, for example, about 14 nm. A fifth layer 78 is disposed over the fourth layer 76 and comprises silicon dioxide (SiO₂). The fifth layer 78 may have a fifth average thickness of greater than or equal to about 245 nm to less than or equal to about 280 nm, for example, about 250 nm or alternatively, about 273 nm.

In yet another variation, the multilayer stack 54 forming the chrome-like material comprises five layers 56 over substrate 52. A first layer 70 is adjacent to the substrate 52 and comprises nickel (Ni). The first layer 70 may have a first average thickness of greater than or equal to about 95 nm to less than or equal to about 105 nm, for example, about 100 nm. A second layer 72 is disposed over the first layer 70 and comprises aluminum oxide (Al₂O₃). The second layer 72 may have a second average thickness of greater than or equal to about 95 nm to less than or equal to about 165 nm, for example, about 98 nm or alternatively about 160 nm. A third layer 74 is disposed over the second layer 72 and comprises germanium (Ge). A third average thickness of the third layer 74 may be greater than or equal to about 7 nm to less than or equal to about 15 nm, for example, about 8 nm or 13 nm. A fourth layer 76 is disposed over the third layer 74 and comprises zinc (Zn). The fourth layer 76 may have a fourth average thickness of greater than or equal to about 12 nm to less than or equal to about 17 nm, for example, about 14 nm. A fifth layer 78 is disposed over the fourth layer 76 and comprises hafnium oxide (HfO₂). The fifth layer 78 may have a fifth average thickness of greater than or equal to about 5 nm to less than or equal to about 15 nm, for example, about 7 nm or alternatively, about 12 nm.

In yet a further variation, the multilayer stack 54 forming the chrome-like material comprises five layers 56 over substrate 52. A first layer 70 is adjacent to the substrate 52 and comprises zinc (Zn). The first layer 70 may have a first average thickness of greater than or equal to about 95 nm to less than or equal to about 105 nm, for example, about 100 nm. A second layer 72 is disposed over the first layer 70 and comprises silicon dioxide (SiO₂). The second layer 72 may have a second average thickness of greater than or equal to about 80 nm to less than or equal to about 125 nm, for example, about 83 nm or alternatively about 122 nm. A third layer 74 is disposed over the second layer 72 and comprises germanium (Ge). A third average thickness of the third layer 74 may be greater than or equal to about 10 nm to less than or equal to about 15 nm, for example, about 10 nm or alternatively, about 15 nm. A fourth layer 76 is disposed over the third layer 74 and comprises tungsten (W). The fourth layer 76 may have a fourth average thickness of greater than or equal to about 12 nm to less than or equal to about 17 nm, for example, about 13 nm or in alternative aspects, about 15 nm. A fifth layer 78 is disposed over the fourth layer 76 and comprises hafnium oxide (HfO₂). The fifth layer 78 may have a fifth average thickness of greater than or equal to about 100 nm to less than or equal to about 125 nm, for example, about 105 nm or alternatively, about 120 nm.

In another variation, the multilayer stack 54 forming the chrome-like material comprises three layers 56 over substrate 52. This embodiment is free of not only chromium (Cr), but all metals. A first layer 70 is adjacent to the substrate 52 and comprises germanium (Ge). The first layer 70 may have a first average thickness of greater than or equal to about 30 nm to less than or equal to about 35 nm, for example, about 33 nm. A second layer 72 is disposed over the first layer 70 and comprises silicon dioxide (SiO₂). The second layer 72 may have a second average thickness of greater than or equal to about 117 nm to less than or equal to about 122 nm, for example, about 119 nm. A third layer 74 is disposed over the second layer 72 and comprises germanium (Ge). A third average thickness of the third layer 74 may be greater than or equal to about 19 nm to less than or equal to about 24 nm, for example, about 21 nm.

In this manner, the three active layer stack free of any metals can be used to form a radiofrequency (RF)-transparent material having a chrome-like appearance. The material may comprise a substrate that displays a transparency to radiofrequency (RF) electromagnetic radiation of greater than or equal to about 60% of wavelengths of greater than or equal to about 1 mm to less than or equal to about 10 km are transmitted. A multilayer stack is disposed on the substrate that comprises at least three material layers, wherein at least two material layers are compositionally distinct from one another and each material layer is independently selected from the group consisting of: germanium (Ge), titanium oxide (TiO₂), silicon dioxide (SiO₂), and combinations thereof. As noted above, in one variation, the multilayer stack may comprise a first layer is disposed on the substrate and comprises germanium (Ge), a second layer is disposed over the first layer and comprises silicon dioxide (SiO₂), and a third layer is disposed over the second layer and comprises germanium (Ge). The material is free of any metals. The material further displays a specular reflectivity where greater than or equal to about 70% of wavelengths of greater than or equal to about 390 nm to less than or equal to about 750 nm are reflected by the material without scattering, and displays a transparency to radiofrequency (RF) electromagnetic radiation where greater than or equal to about 60% of wavelengths of greater than or equal to about 1 mm to less than or equal to about 10 km are transmitted. In certain variations, each of the material layers has a thickness of greater than or equal to about 15 nm to less than or equal to about 150 nm.

In one variation, the first layer is disposed on the substrate and comprises germanium (Ge) and has a first average thickness of about 33 nm, the second layer comprises silicon dioxide (SiO₂) disposed on the first layer and has a second average thickness of about 119 nm, and third layer comprises germanium (Ge) disposed on the second layer that has a third average thickness of about 21 nm.

In certain variations, a device comprising the radiofrequency (RF)-transparent material like those described above may be selected from the group consisting of: a vehicle component, a consumer product (e.g., an appliance, plumbing), a mobile device, a decoration, trim, building walls or sections of walls, surveillance systems, and combinations thereof

FIG. 1B shows an alternative material 50A having a chrome-like appearance that is free of any chromium (Cr). To the extent that material 50 in FIG. 1A shares features with the alternative material 50A, for brevity, these will not be discussed again herein. In addition to a substrate 52 and a multilayer stack 54, the alternative material 50A includes a protective coating layer 80 disposed on the outermost surface of the final active layer (shown as fifth layer 78 of the multilayer stack 54) that is exposed to an external environment. The protective coating layer 80 may be a polymeric or ceramic coating material that is transparent to visible light. The protective coating layer 80 may be continuous over a surface 68 of the material and hydrophobic and thus minimize infiltration of water, ultraviolet radiation, and other contaminants from destabilizing the materials multilayer stack 54. Protective coating layer 80 material may include UV or thermally cured polymer resin or liquor with sufficient transparency, hardness and scratch resistance, as are known in the art.

As background, to design a thin film structure that can produce the desired chromium reflection spectrum, the task is formulated in the RL-design approach as an inverse design problem, in which multilayer structures are designed to achieve a certain optical response, namely the predetermined reflection spectrum in visible range to mimic chrome-plating. However, the design process can be non-trivial because for each layer, both material selection and thickness need to be considered. The wavelength-dependent nature of the refractive index of a material can worsen this situation when designing in a broadband wavelength region, e.g., the entire visible light region. To make this easier, many optimization-based methods have been devised to design thin film structures, including needle optimization, particle swarm optimization (PSO), genetic algorithms, etc. However, these methods are usually based on heuristic searching without learning from experience, which can lead to suboptimal performance. Additionally, as the number of layers in the design increases, the search space for the structures increases exponentially, which makes the search for good designs inefficient and challenging. Recently, many machine learning-based methods have been proposed and demonstrated good performance for inverse design. Here, Reinforcement Learning (RL) algorithm in the form of Optical MultiLayer-Proximal Policy Optimization (OML-PPO) is used, which learns from its past results when searching within a large space.

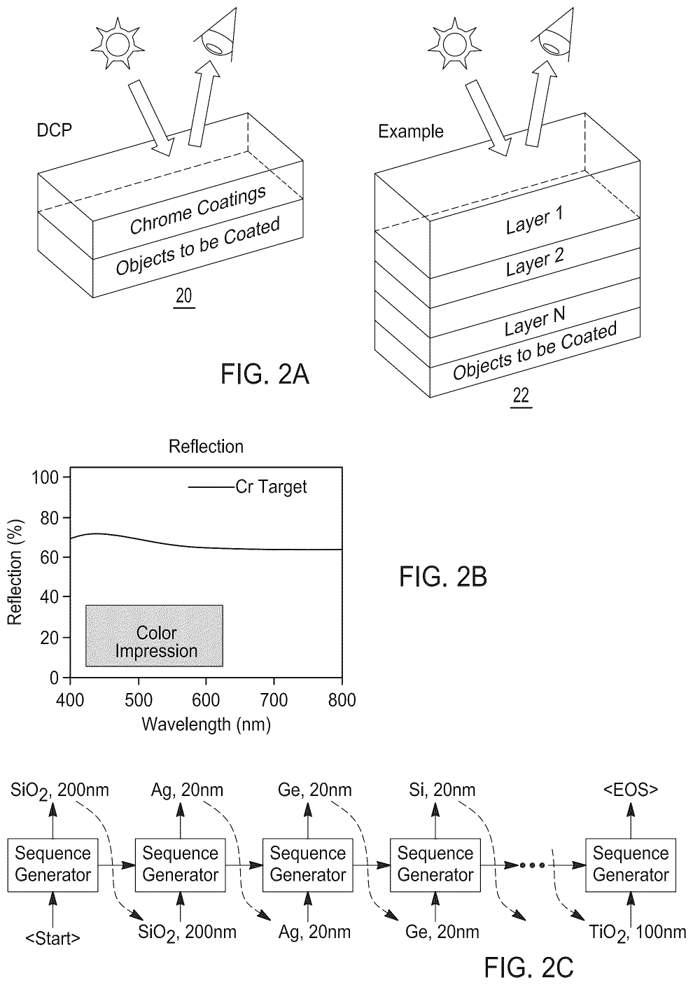

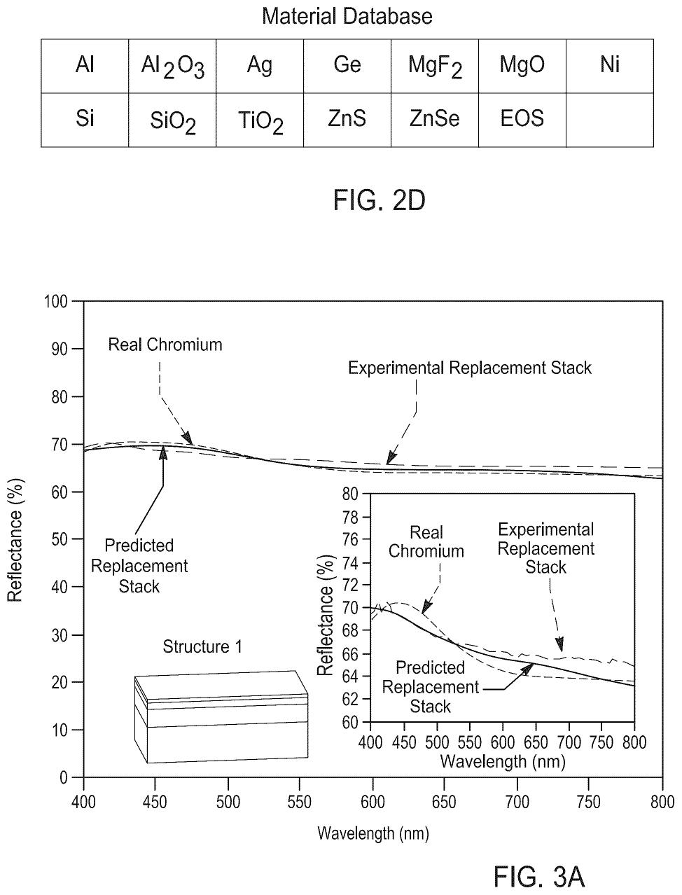

In this inverse design problem, the target is to produce the same reflection spectrum as that of chrome-coated objects. FIG. 2A shows a conventional Decorative Chrome Plating (DCP) object 20 and an object 22 having an inventive chrome-like multilayer coating free of any chromium in accordance with certain aspects of the present disclosure. For a multilayer thin film structure 22 as A shown on the right in FIG. 2A, each layer can be expressed as sₗ=[mₗ, dₗ], where mₗ is the material selection and dₗ is the corresponding thickness at the lₜₕ layer. The sequence S={s₁, s₂, s₃, . . . , S_{N}}, ={[m₁, d₁], [m₂, d₂], . . . , [m_{N}, d_{N}]} can also be used to describe the overall thin film structure, where N is the total number of layers. Therefore, designing such a structure is to find a specific sequence of material and thickness combination that gives the desired target optical response. The design steps that OML-PPO uses are represented in FIG. 2C. For the lₜₕ layer, the RL algorithm takes the designed layers from previous steps and predicts the material mₗ and thickness dₗ sequentially. This design process automatically stops when the designed stack reaches the maximum number of layers L (here we set L=5). At each step, the material mₗ is selected from a list of materials in the database as shown in FIG. 2D. Twelve materials (both dielectrics and metals) were included in the database for the design based on their availability, non-toxicity, and ease of deposition, namely aluminum (Al), aluminum oxide (Al₂O₃), silver (Ag), germanium (Ge), magnesium fluoride (MgF₂), magnesium oxide (MgO), nickel (Ni), silicon (Si), silicon dioxide (SiO₂), titanium dioxide (TiO₂), zinc sulfide (ZnS), and zinc selenide (ZnSe). The refractive indices of these materials deposited by PVD were experimentally measured by using spectroscopic ellipsometry. One faux material is used as an indicator of the End-Of-Sequence (EOS). Once the algorithm selects EOS, the design process stops immediately irrespective of whether the designed structure has reached the maximum number of layers. This can be used to design structures with a variable number of layers (for example, 3, 4, 5 layers when L=5). The layer thickness is set to be in the range of 5 nm to 250 nm, discretized by a 5 nm gap (corresponding to 50 thickness selections in total). In this way, the total search space spans to (13×50)⁵ to 10¹⁴ different combinations of structures, which is an incredibly challenging task for traditional optimization methods to deal with.

In order to simplify the task, only the normal reflection in the visible range is considered and set the design target to be the Cr reflection spectrum Rₜ, which is shown in FIG. 2B. The inset figure in FIG. 2B also shows an example of the shiny reflective Cr color. The Transfer Matrix Method (TMM) is used to simulate the reflection spectrum R_{d} of the layered structure. During the design process, the difference between the designed spectrum R_{d} and the target spectrum Rₜ is minimized. Since RL algorithm learns to design multilayer structures by maximizing the reward, the reward Gₜ is defined to be 1 minus the spectrum difference and express the rewards as:

$${G}_{t} = 1 - \frac{1}{n} {\sum }_{i = 1}^{n} {( {R}_{t} ( S , {λ}_{i} ) - {R}_{d} ( S , {λ}_{i} ) )}^{2} \qquad ( 1 )$$

where λᵢ is the wavelength which ranges from 40° nm to 80° nm with 5 nm increments. After the design process, the best discovered structure is selected and PSO is used to further fine tune the thickness at each layer, which can eliminate the influence of thickness discretization and improve the performance of the prediction. The fine-tuned structure is then the final design.

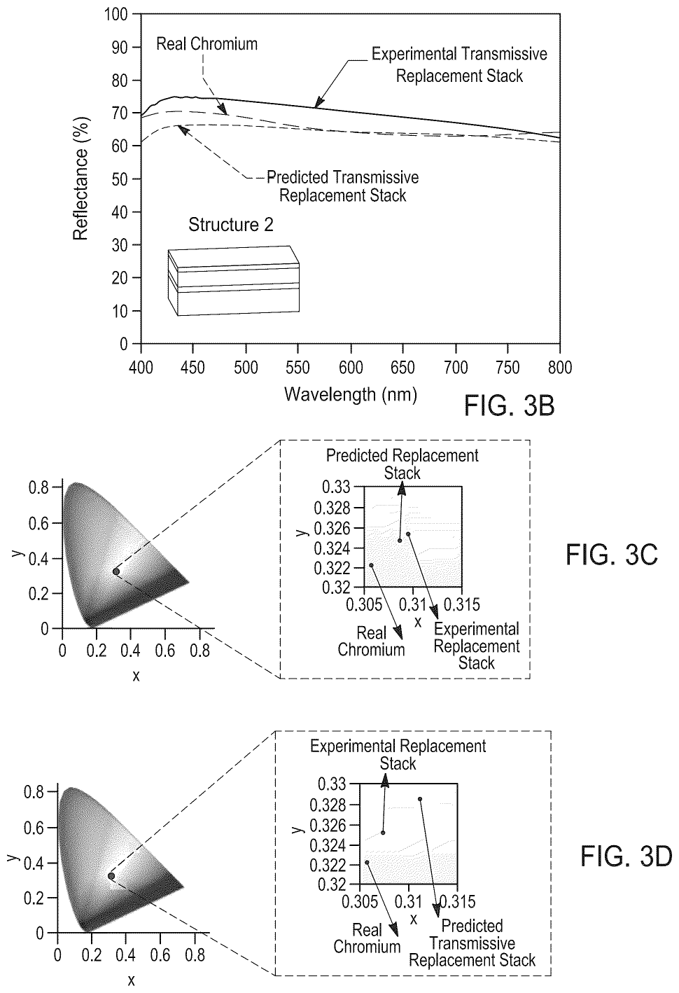

Using the RL algorithm described in the methods, several structures are designed as potential replacements for DCP, two of which are chosen to experimentally deposit due to ease of fabrication, as shown in FIGS. 3A (designated “Structure 1 or S1”) and 3B (designated “Structure 2 or S2”). Structure 1 (S1) going from top to bottom, includes: Ge (thickness of about 19 nm)/TiO₂ (thickness of about 17 nm)/SiO₂ (thickness of about 82 nm)/Ni (thickness of about 139 nm)/glass substrate. Structure 2 (S2) going from top to bottom includes Ge (thickness of about 21 nm)/SiO₂ (thickness of about 119 nm)/Ge (thickness of about 33 nm)/glass substrate. As noted above, because there are no metals in S2, it can allow high transmission in radio frequencies, providing a multi-functional property to DCP for microwave applications, which will be discussed later. These two structures were fabricated using electron beam evaporation as described further below.

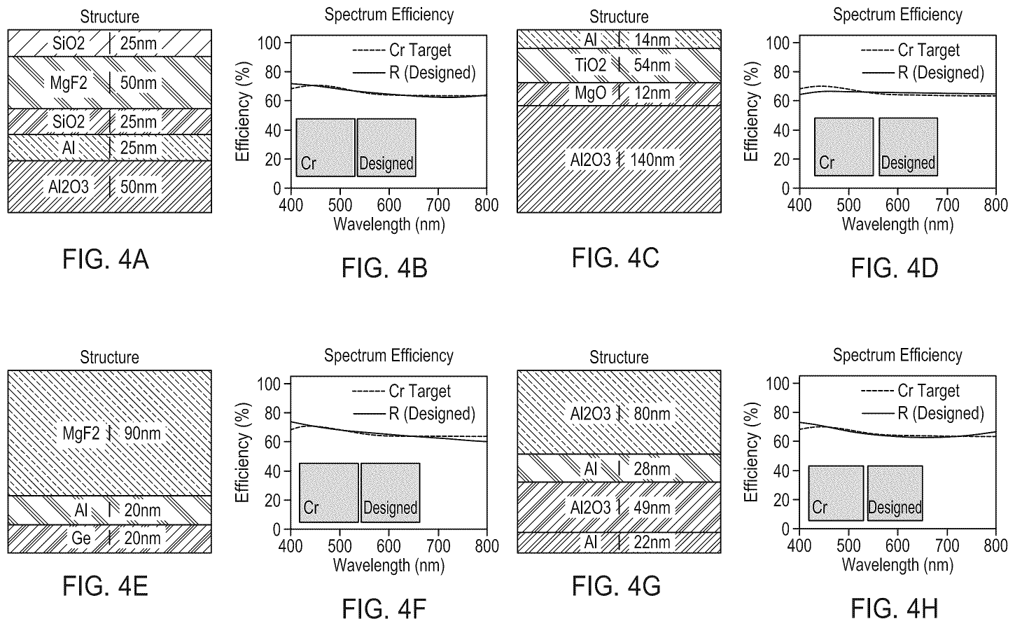

Other designed structures with simulation results can be found in FIGS. 4A-4H. The structure in FIG. 4A going from top to bottom, includes: SiO₂ (thickness of about 25 nm)/MgF₂ (thickness of about 50 nm)/SiO₂ (thickness of about 25 nm)/Al (thickness of about 25 nm)/Al₂O₃ (thickness of about 25 nm)/glass substrate. A simulated reflection spectrum for this structure is shown in FIG. 4B. The structure in FIG. 4C going from top to bottom, includes: Al (thickness of about 14 nm)/TiO₂ (thickness of about 54 nm)/MgO (thickness of about 12 nm)/Al₂O₃ (thickness of about 50 nm)/glass substrate. A simulated reflection spectrum for this structure is shown in FIG. 4D. The structure in FIG. 4E going from top to bottom, includes: MgF₂ (thickness of about 90 nm)/Al (thickness of about 20 nm)/Ge (thickness of about 20 nm)/glass substrate. A simulated reflection spectrum for this structure is shown in FIG. 4F. The structure in FIG. 4G going from top to bottom, includes: Al₂O₃ (thickness of about 80 nm)/Al (thickness of about 28 nm)/Al₂O₃ (thickness of about 49 nm)/Al (thickness of about 22 nm)/glass substrate. A simulated reflection spectrum for this structure is shown in FIG. 4H.

Various embodiments of the inventive technology can be further understood by the specific examples contained herein. Specific Examples are provided for illustrative purposes of how to make and use the compositions, devices, and methods according to the present teachings and, unless explicitly stated otherwise, are not intended to be a representation that given embodiments of this invention have, or have not, been made or tested.

### Example 1

Each of the layers used in the replacement stack in accordance with certain variations of the present disclosure were individually evaporated via an electron beam evaporation process on a 0.5 mm thick piece of silicon wafer in an Angstrom Engineering Evovac Evaporator. For Structure S1, the desired thickness for the bottom metal layer, Ni was 138 nm with a deposition rate of 4 Å/sec. SiO₂ (82 nm) was deposited at a rate of 3 Å/see, TiO₂ (18 nm) was deposited at 2 Å/see, and Ge (17 nm) was deposited at 2 Å/sec. For Structure S2, the Ge and SiO₂ were deposited at the same rates as in S1.

Material characterization was conducted using the J. A. Woollam M-2000 (wavelength range: 400-1600 nm, three angles of incidence: 65°, 70°, and 75°) for spectroscopic ellipsometry to measure the thickness of the evaporated films. This was also used to determine the optical constants such as the real and imaginary parts of the refractive index of the films. A B-spline model was used for fitting data from metals and dielectrics. Reflectance spectra were measured using a portable normal incidence spectrometer integrated with a white light source. It included an HR4000 Ocean Optics high resolution spectrometer, and the data was acquired using the SpectraSuite software.

A MATLAB simulation based on the transfer matrix method (TMM) was used to verify the prediction from the machine learning algorithm and the experimental data obtained. Optical constant data for the materials were obtained using ellipsometry.

The RF measurements were conducted with the use of a Keysight network analyzer, model E5080B-2K0 and a set of waveguides in the WR90 size (width 22.86 mm, height 10.16 mm) covering a frequency range of 8.2 GHz to 12.4 GHz. The setup was calibrated using three calibration loads: a short (a flat metal plate), an offset short (flat metal plate with a little bit of waveguide pipe before the flat part), and a matched load (no reflections). These calibration loads were made in-house in the RF measurement laboratory.

In FIGS. 3A and 3B, predicted (green) and measured (blue) reflection spectrum at normal incidence of Structures S1 and S2, respectively, are shown. The spectrum was measured using a normal incidence spectrometer. For a better comparison, the reflection spectrum of real chromium (Cr) (red) at normal incidence is also shown in each figure. Chromium has a broadband reflection spectrum across the optical wavelength range. For both structures, the predicted and measured spectrum show a broadband reflection trend which agrees very well with the actual Cr spectrum. For S1, the three spectra overlap with each other so an inset (lower right) in FIG. 3A is used to magnify the differences. In FIG. 3B, for S2, the predicted spectrum is found to differ from the Cr spectrum in the shorter wavelength region which can be attributed to restrictions on material selections (excluding metals) in the algorithm. While the predicted and measured spectra trends agree well, the reflection values differ somewhat. The experimental reflection spectrum for S2 (FIG. 3B) near 400 nm is around 70% and falls close to 65% at 800 nm. These discrepancies in the experimental results can be attributed to slight thickness variations during deposition.

However, these small differences in the reflectance of the predicted and experimental stacks compared to real chromium do not impact the overall color appreciably. In FIGS. 3C and 3D, the combined RGB data from the predicted, measured, and real chrome spectra are compared on the CIE 1931 chromaticity plot for Structures S1 and S2 respectively. All three colors overlap well for both structures and lie in the middle of the CIE plot, indicating a Cr color as desired. In each figure, the expanded view of the CIE color map further demonstrates that the differences between the colors in the three spectra are minimal.

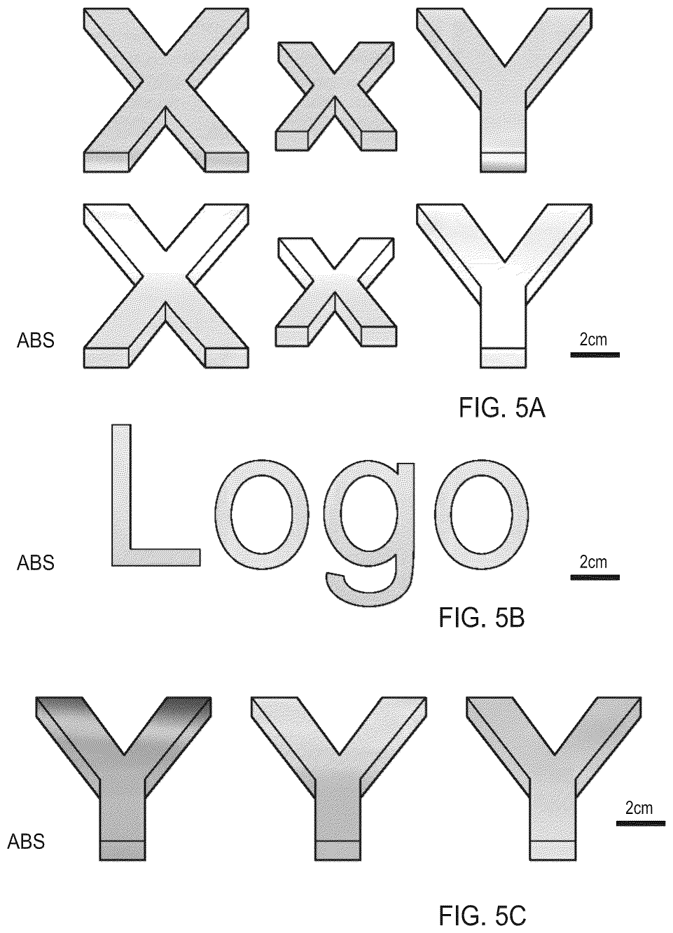

Since the design target is reflection and there is no light transmitting through the bottom layer, the chrome-mimicking color can be produced on different substrates as long as film deposition on the substrate is feasible. The robustness of the design is demonstrated by depositing the same chrome-mimicking structure on other types of substrates, e.g., ABS plastic, which is widely used in many practical applications. An example of this is demonstrated by depositing the replacement stack on top of ABS plastic pieces that are often used as markers on the back of automobiles such as ‘X×Y’, or a commercial logo, see e.g., “Logo.” FIG. 5A shows a comparison of ABS plastic pieces (the letters/numbers ‘X×Y’) coated using either commercially coated chromium finish (top) or the inventive replacement stack Structure S1 (bottom). Visually, one can observe the replacement stack S1 is very similar to the conventionally commercially coated Cr.

FIG. 5B shows a sample of black ABS plastic coated with replacement stack Structure S2 which appears to be visually similar to a real Cr coating while having the added advantage of being RF transmissive. One unique aspect of the inventive technology is that it can easily create different “tones” of chrome color by adjusting the stack parameters. In FIG. 5C, the appearance of a piece of ABS plastic coated with PVD chrome (top) is shown, one with an inventive stack Structure S1 (middle), and one with an inventive stack Structure S1 with a green hue S1′ (bottom). The bottom structure, S1′ in FIG. 5C includes a stack of Ge (8 nm)/SiO₂ (139 nm)/Ni (138 nm) on a glass substrate, which is fine-tuned from S1. FIG. 5C also demonstrates a color difference between a PVD based Cr-coating and a multilayer stack prepared in accordance with certain aspects of the present disclosure. Using an evaporation-based alternative process to deposit a chromium-like finish is more desirable, because PVD chromium renders a color that is significantly darker than electrodeposited chromium.

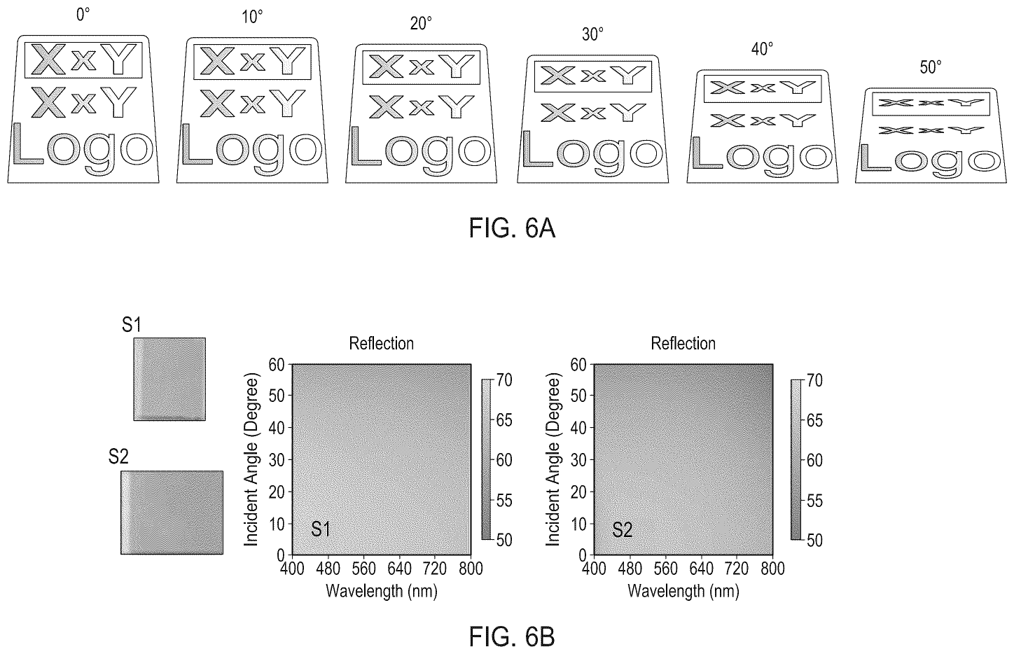

Apart from substrate independence, the multilayer stack chrome-like replacement coatings prepared in accordance with certain aspects of the present disclosure are also angle-independent, just like a real chromium containing DCP coating. FIG. 6B (center and right) shows the simulated angle-resolved reflection spectrum of the two design structures on glass substrates (S1 and S2 respectively). At viewing angles up to 50°, the reflection always exhibits a flat spectrum with an amplitude that is consistently between 60% to 70%. This angle robustness is also observed when using ABS substrates. FIG. 6A reflects comparison of two fabricated replacement stacks (Si center, S2 bottom) and real chrome (top) at different viewing angles. The angle is varied from 0° to 50°, and as can be observed, the appearance is consistent with that of chromium.

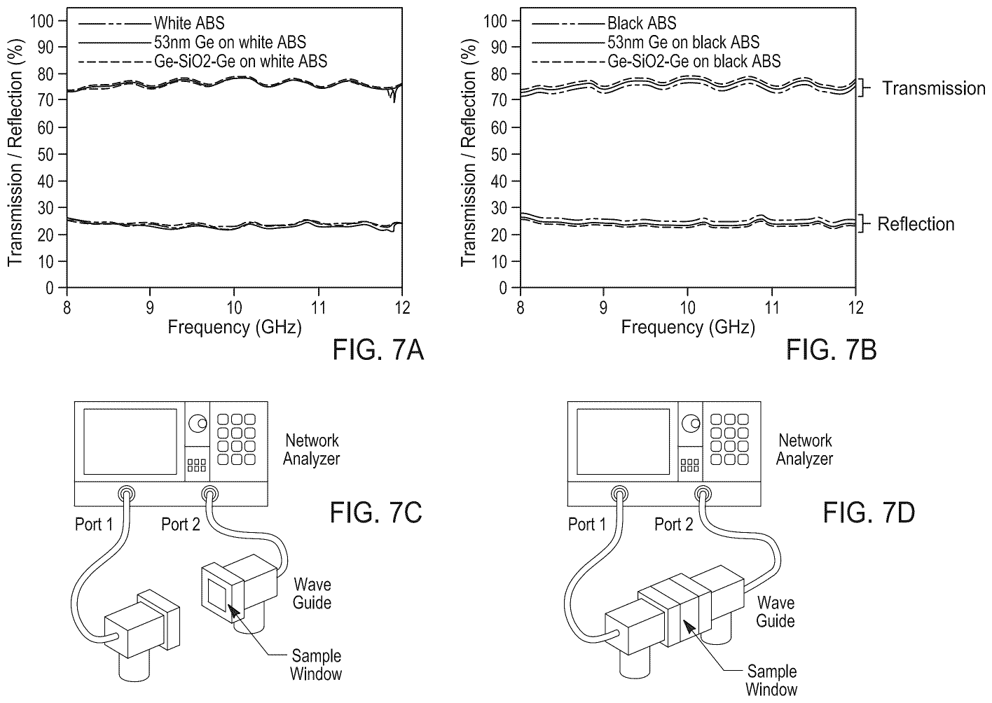

Commercial DCP-coated objects block RF signals because metals (chrome in DCP) are highly reflective in such frequencies. Thus, they are seldom used in RF-based devices, e.g., automobile radars. Semiconductor materials such as Ge have much smaller losses in the RF regime, so Structure S2 is designed as another chrome-mimicking multilayer stack that also simultaneously has high transmission in the RF regime, as the structure involves thin layers of Ge and SiO₂ only. To demonstrate this, the transmission and reflection of S2 in the range of 8-12 GHz are experimentally measured as shown in FIGS. 7A-7D. This was done by using a WR90 waveguide to accommodate such frequencies and a Keysight network analyzer for measurement. The measurement setup is shown in FIG. 7C and the waveguide is in FIG. 7D. The sample was handcrafted to fit into the cross-section of the waveguide with the coated sides facing port 1. The structure was deposited on two types of ABS plastic: white (2.6 mm thick) and black (3 mm thick). For each substrate, the RF transmission of (1) the substrate without any coating, (2) the substrate coated with a 53 nm layer of Ge (the combined thickness of the two Ge layers in S2), and (3) the substrate coated with S2 structure were all tested. By analyzing the Sparameters (S21 for transmission from port 2 to 1 and S11 for reflection back to port 1) the transmission and reflection are found to remain very close to that of a pristine substrate and are independent of the substrate used as shown in FIGS. 7A-7B. The ripples in the measured data are due to frequency-matching calibration errors. RF transmission through glass substrates coated with S2 is also tested similarly. Thus, the results suggest that the Structure S2 prepared in accordance with certain aspects of the present disclosure is a multi-functional coating that yields a similar appearance as DCP, while providing high transmission in the RF region, which is impossible using traditional metal coatings.

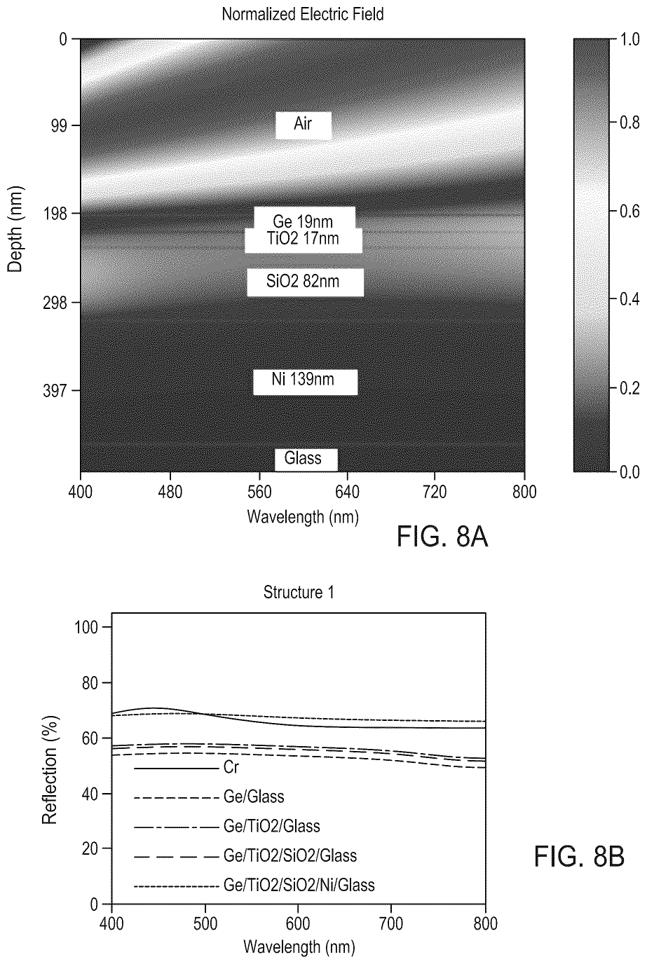

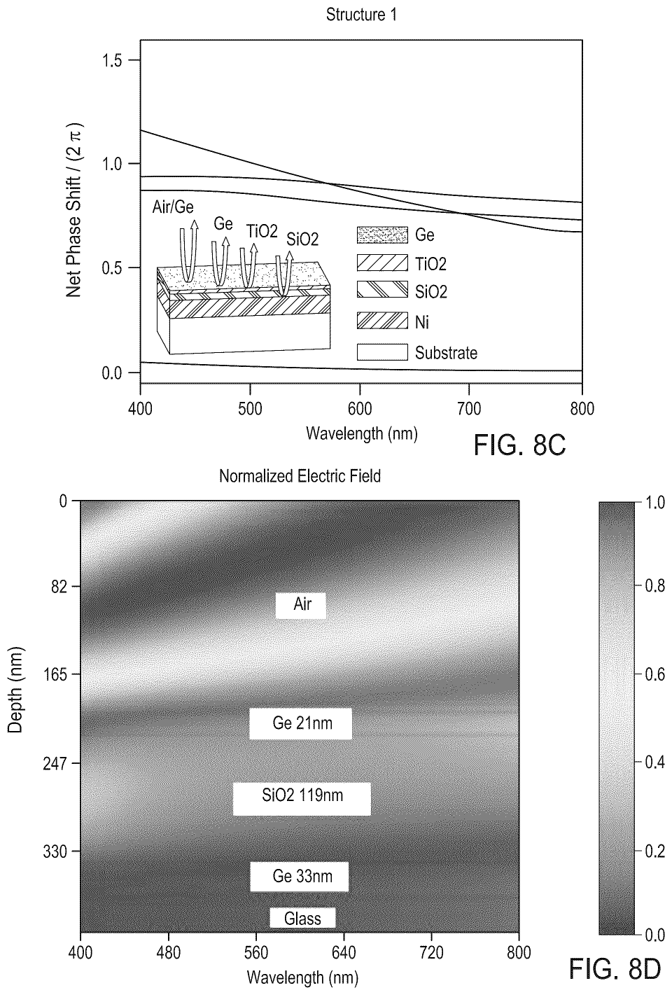

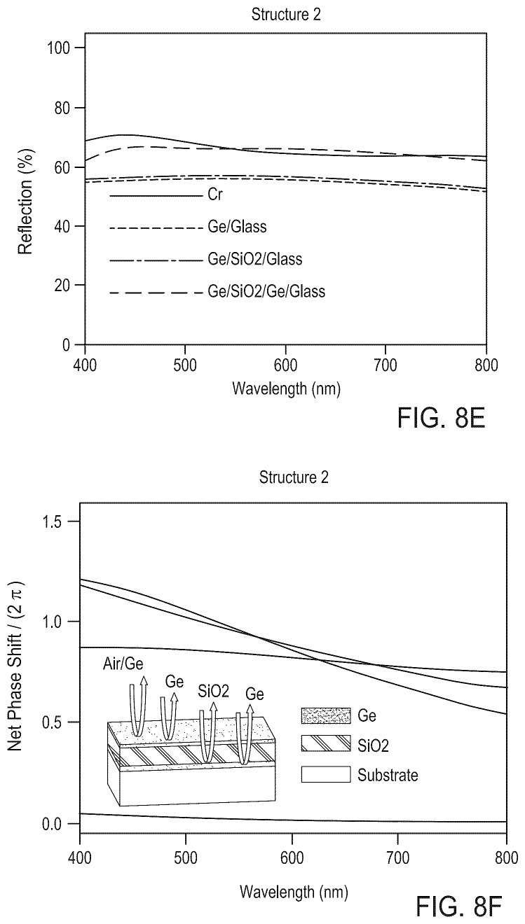

In FIGS. 8A and 8D, the normalized electric field intensity for Structures S1 and S2 are mapped, respectively. The strong electric field in air across the whole visible range indicates the high broadband reflectance of both structures. Simulated absorption further suggests that the remaining light is absorbed mainly by the top Ge layer. To understand why the chrome-mimicking structures produce a reflection spectrum similar to Cr (flat spectrum with approximately 70% reflection over visible range), the design process and simulated the reflection of the designed structures is examined step-by-step. The reflection of a single Ge layer on top of a glass substrate is first analyzed. In FIGS. 8B and 8E, the orange dashed lines are the simulated reflection spectrum of the 19 nm Ge and 21 nm Ge on the glass substrate, which corresponds to the top layers of structures S1 and S2, respectively (in FIG. 8E, the orange line and green line overlap with each other). A significant portion of light (approximately 50%) is reflected at the Air-Ge interface since Ge has a high refractive index. However, compared to the target Cr reflection (approximately 70%), such a thin layer of Ge still provides a much lower reflection. The remaining light transmitted through the air-Ge interface is absorbed in the Ge layer or further transmitted through to the next layer. For both structures, the next layer(s) is composed of dielectric material(s). S1 has two consecutive dielectric layers, 17 nm TiO₂ and 82 nm SiO₂ while S2 has one, 119 nm SiO₂. The green dashed lines in FIGS. 8B and 8E are the simulated reflection spectrum of 19 nm Ge/17 nm TiO₂/82 nm SiO₂ and 21 nm Ge/119 nm SiO₂ on glass substrate. Since dielectric materials do not reflect or absorb strongly, these additional layers only add a propagation phase and most of the light is transmitted directly. In the final layers, S1 has a thick layer of Ni as the bottom layer while S2 has a 33 nm Ge layer. Both final layers work as reflective mirrors to boost the reflection from about 50% to about 70% by reflecting the transmitted light back to the upper layers. The red dashed lines in FIGS. 8B and 8E are their corresponding reflection spectra and are very close to the target Cr reflection. To better see this, in FIGS. 8C and 8F, the net phase shift at each layer is calculated, which includes the reflection phase between the top and bottom interfaces as well as the accumulated propagation phase through the dielectric layers. The net phase shift inside the thick Ni layer is not shown because most light that propagates up to its skin depth gets absorbed. For both structures, adding the dielectric materials makes the net phase shift at the bottom layer close to 2π, which leads to constructive interference that increases the overall reflection to produce a Cr-like spectrum.

In this example, two novel chrome-like multilayer films structures for DCP replacement are tested, offering a visual appearance identical to that of real Cr, while completely eliminating the harmful Cr electroplating process. The structures are designed by the OML-PPO algorithm based on reinforcement learning. Two of many RL-designed structures were fabricated and their visual resemblance to Cr coatings was demonstrated. The structures were robust to a wide viewing angle and a variety of substrates. Multi-functionality can be designed into the target response, for example, one structure exhibits high transmission in the RF region, a function that conventional chromium-containing coatings cannot have.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A material having a chrome-like appearance comprising:
a substrate; and
a multilayer stack disposed on the substrate that comprises at least three material layers, wherein at least two material layers are compositionally distinct from one another and each material layer independently comprises a composition selected from:
a first composition comprising an optically transparent dielectric material selected from the group consisting of: titanium oxide (TiO₂), silicon dioxide (SiO₂), magnesium fluoride (MgF₂), magnesium oxide (MgO), aluminum oxide (Al₂O₃), hafnium oxide (HfO₂), zirconium dioxide (ZrO₂), zinc sulfide (ZnS), zinc selenide (ZnSe), zinc oxide (ZnO), silicon nitride (Si₃N₄), silicon dioxide (SiO₂), tin oxide (SnO₂), and combinations thereof;
a second composition comprising a light absorbing material comprising an element selected from Groups 13 to 16 of the IUPAC Periodic Table; or
a third composition comprising a light reflecting material selected from the group consisting of: nickel (Ni), aluminum (Al), copper (Cu), silver (Ag), gold (Au), tungsten (W), zinc (Zn), platinum (Pt), titanium (Ti), titanium nitride (TiN), and combinations thereof,
wherein the material is free of chromium (Cr) and displays a specular reflectivity such that greater than or equal to about 50% of wavelengths in a visible light range of greater than or equal to about 390 nm to less than or equal to about 750 nm are reflected by the material without scattering.

2. The material of claim 1, wherein the second composition comprises a light absorbing material selected from the group consisting of: silicon (Si), germanium (Ge), silicon carbide (SiC), gallium nitride (GaN), gallium phosphide (GaP), zinc sulfide (ZnS), zinc selenide (ZnSe), iron oxides, chalcogenides, and combinations thereof.

3. The material of claim 1, wherein the multilayer stack defines a first side adjacent to the substrate and a second side opposite to the first side defining a terminal material layer, wherein the terminal material layer comprises the third composition comprising the light reflecting material and the multilayer stack further comprises one or more intermediate material layers comprising the first composition comprising the optically transparent dielectric material disposed between the terminal material layer and the substrate.

4. The material of claim 3, further comprising at least one second intermediate material layer disposed between the substrate and the terminal material layer that comprises the second composition comprising the light absorbing material disposed between the terminal material layer and the substrate.

5. The material of claim 3, wherein the multilayer stack comprises one of the following:
(a) three distinct material layers, wherein a first material layer adjacent to the substrate comprises silicon nitride (Si₃N₄), a second material layer comprises silicon (Si), and the terminal material layer comprises aluminum (Al); or
(b) three distinct material layers, wherein a first material layer adjacent to the substrate comprises zinc sulfide (ZnS), a second material layer comprises magnesium fluoride (Mg₂F), and the terminal material layer comprises silver (Ag); or
(c) four distinct material layers, wherein a first material layer adjacent to the substrate comprises aluminum oxide (Al₂O₃), a second material layer comprises magnesium oxide (MgO), a third material layer comprises titanium dioxide (TiO₂), and the terminal material layer comprises aluminum (Al).

6. The material of claim 1, wherein the multilayer stack defines a first side adjacent to the substrate and a second side opposite to the first side defining a terminal material layer, wherein the terminal material layer comprises the second composition comprising the light absorbing material and the multilayer stack further comprises one or more intermediate material layers disposed between the terminal material layer and the substrate and comprising the first composition comprising the optically transparent dielectric material.

7. The material of claim 6, further comprising at least one intermediate material layer disposed between the terminal material layer and the substrate comprising the second composition comprising the light absorbing material.

8. The material of claim 6, wherein the first side of the multilayer stack comprises a bottom material layer adjacent to the substrate that comprises the third composition comprising the light reflecting material.

9. The material of claim 6, wherein the multilayer stack comprises one of the following:
(a) three distinct material layers, wherein a first material layer adjacent to the substrate comprises germanium (Ge), a second material layer comprises silicon dioxide (SiO₂), and the terminal material layer comprises germanium (Ge);
(b) four distinct material layers, wherein a first material layer adjacent to the substrate comprises nickel (Ni), a second material layer comprises silicon dioxide (SiO₂), a third material layer comprises titanium dioxide (TiO₂), and the terminal material layer comprises germanium (Ge); or
(c) four distinct material layers, wherein a first material layer adjacent to the substrate comprises silver (Ag), a second material layer comprises tin oxide (SnO₂), a third material layer comprises magnesium fluoride (MgF₂), and the terminal material layer comprises silicon (Si).

10. The material of claim 1, wherein the multilayer stack defines a first side defining a bottom material layer adjacent to the substrate and a second side opposite to the first side defining a terminal material layer, wherein the terminal material layer comprises the first composition comprising the optically transparent dielectric material and the bottom material layer comprises the third composition comprising the light reflecting material.

11. The material of claim 10, wherein the multilayer stack further comprises at least one intermediate material layer disposed between the bottom material layer and the terminal material layer comprising the first composition comprising the optically transparent dielectric material.

12. The material of claim 10, wherein the multilayer stack further comprises at least one intermediate material layer disposed between the bottom material layer and the terminal material layer comprising the second composition comprising the light absorbing material.

13. The material of claim 10, wherein the multilayer stack comprises one of the following:
(a) three distinct material layers, wherein a first material layer adjacent to the substrate comprises germanium (Ge), a second material layer comprises aluminum (Al), and the terminal material layer comprises magnesium fluoride (MgF₂);
(b) three distinct material layers, wherein a first material layer adjacent to the substrate comprises aluminum (Al), a second material layer comprises silicon dioxide (SiO₂), and the terminal material layer comprises zinc oxide (ZnO);
(c) three distinct material layers, wherein a first material layer adjacent to the substrate comprises silver (Ag), a second material layer comprises zinc selenide (ZnSe), and the terminal material layer comprises zinc oxide (ZnO);
(d) four distinct material layers, wherein a first material layer adjacent to the substrate comprises aluminum (Al), a second material layer comprises aluminum oxide (Al₂O₃), a third material layer comprises aluminum (Al), and the terminal material layer comprises aluminum oxide (Al₂O₃);
(e) five distinct material layers, wherein a first material layer adjacent to the substrate comprises aluminum oxide (Al₂O₃), a second material layer comprises aluminum (Al), a third material layer comprises silicon dioxide (SiO₂), a fourth material layer comprises magnesium fluoride (MgF₂), and the terminal material layer comprises silicon dioxide (SiO₂);
(f) five distinct material layers, wherein a first material layer adjacent to the substrate comprises gold (Au), a second material layer comprises magnesium fluoride (MgF₂), a third material layer comprises germanium (Ge), a fourth material layer comprises zinc (Zn), and the terminal material layer comprises hafnium oxide (HfO₂);
(g) five distinct material layers, wherein a first material layer adjacent to the substrate comprises gold (Au), a second material layer comprises aluminum oxide (Al₂O₃), a third material layer comprises germanium (Ge), a fourth material layer comprises zinc (Zn), and the terminal material layer comprises hafnium oxide (HfO₂);
(h) five distinct material layers, wherein a first layer adjacent to the substrate comprises gold (Au), a second material layer comprises silicon dioxide (SiO₂), a third material layer comprises germanium (Ge), a fourth material layer comprises silver (Ag), and the terminal material layer comprises silicon dioxide (SiO₂);
(i) five distinct material layers, wherein a first material layer adjacent to the substrate comprises nickel (Ni), a second material layer comprises aluminum oxide (Al₂O₃), a third material layer comprises germanium (Ge), a fourth material layer comprises zinc (Zn), and the terminal material layer comprises hafnium oxide (HfO₂);
(j) five distinct material layers, wherein a first material layer adjacent to the substrate comprises zinc (Zn), a second material layer comprises silicon dioxide (SiO₂), a third material layer comprises germanium (Ge), a fourth material layer comprises tungsten (W), and the terminal material layer comprises hafnium oxide (HfO₂);
(k) five distinct material layers, wherein a first layer adjacent to the substrate comprises aluminum oxide (Al₂O₃), a second layer comprises aluminum (Al), a third layer comprises silicon dioxide (SiO₂), a fourth layer comprises magnesium fluoride (MgF₂), and the terminal material layer comprises silicon dioxide (SiO₂);
(l) five distinct material layers, wherein a first layer adjacent to the substrate comprises gold (Au), a second layer comprises magnesium fluoride (MgF₂), a third layer comprises germanium (Ge), a fourth layer comprises zinc (Zn), and the terminal material layer comprises hafnium oxide (HfO₂);
(m) five distinct material layers, wherein a first layer adjacent to the substrate comprises gold (Au), a second layer comprises aluminum oxide (Al₂O₃), a third layer comprises germanium (Ge), a fourth layer comprises zinc (Zn), and the terminal material layer comprises hafnium oxide (HfO₂);
(n) five distinct material layers, wherein a first layer adjacent to the substrate comprises gold (Au), a second layer comprises silicon dioxide (SiO₂), a third layer comprises germanium (Ge), a fourth layer comprises silver (Ag), and the terminal material layer comprises silicon dioxide (SiO₂);
(o) five distinct material layers, wherein a first layer adjacent to the substrate comprises nickel (Ni), a second layer comprises aluminum oxide (Al₂O₃), a third layer comprises germanium (Ge), a fourth layer comprises zinc (Zn), and the terminal material layer comprises hafnium oxide (HfO₂); or
(p) five distinct material layers, wherein a first layer adjacent to the substrate comprises zinc (Zn), a second layer comprises silicon dioxide (SiO₂), a third layer comprises germanium (Ge), a fourth layer comprises tungsten (W), and the terminal material layer comprises hafnium oxide (HfO₂).

14. The material of claim 1, wherein the specular reflectivity is such that greater than or equal to about 70% of wavelengths in the visible light range of greater than or equal to about 390 nm to less than or equal to about 750 nm are reflected by the material without scattering.

15. The material of claim 1, wherein greater than or equal to about 50% of light reflected from the material has the same band of wavelengths.

16. The material of claim 1, wherein light reflected from the material exhibits a peak range of wavelengths corresponding to a hue.

17. The material of claim 1, wherein the multilayer stack defines a first side adjacent to the substrate and a second side opposite to the first side defining a terminal material layer and the material further comprises a protective coating disposed on the terminal material layer of the multilayer stack, wherein the protective coating is transparent to electromagnetic radiation in the visible light range.

18. The material of claim 1, wherein each of the material layers has an average thickness of greater than or equal to about 15 nm to less than or equal to about 150 nm.

19. The material of claim 1, wherein the substrate is selected from the group consisting of: polymer, a metal, an inorganic dielectric material, and combinations thereof.

20. The material of claim 1, wherein the multilayer stack comprises between three and five distinct material layers.

21. A radiofrequency (RF)-transparent material having a chrome-like appearance, the material comprising:
a substrate that displays a transparency to radiofrequency (RF) electromagnetic radiation of greater than or equal to about 60% of wavelengths of greater than or equal to about 1 mm to less than or equal to about 10 m are transmitted; and
a multilayer stack disposed on the substrate that comprises at least three material layers, wherein at least two material layers are compositionally distinct from one another and each material layer independently comprises a composition selected from:
a first composition comprising an optically transparent dielectric material selected from the group consisting of: titanium oxide (TiO₂), silicon dioxide (SiO₂), magnesium fluoride (MgF₂), magnesium oxide (MgO), aluminum oxide (Al₂O₃), hafnium oxide (HfO₂), zirconium dioxide (ZrO₂), zinc sulfide (ZnS), zinc selenide (ZnSe), zinc oxide (ZnO), silicon nitride (Si₃N₄), silicon dioxide (SiO₂), tin oxide (SnO₂), and combinations thereof; and
a second composition comprising a light absorbing material comprising an element selected from Groups 13 to 16 of the IUPAC Periodic Table,
wherein the material is free of any metals, displays a specular reflectivity where greater than or equal to about 50% of wavelengths in a visible light range of greater than or equal to about 390 nm to less than or equal to about 750 nm are reflected by the material without scattering, and displays a transparency to radiofrequency (RF) electromagnetic radiation where greater than or equal to about 60% of wavelengths of greater than or equal to about 1 mm to less than or equal to about 10 m are transmitted.

22. The radiofrequency (RF)-transparent material of claim 21, wherein the second composition comprises a light absorbing material selected from the group consisting of: silicon (Si), germanium (Ge), silicon carbide (SiC), gallium nitride (GaN), gallium phosphide (GaP), zinc sulfide (ZnS), zinc selenide (ZnSe), iron oxides, and combinations thereof.

23. The radiofrequency (RF)-transparent material of claim 21, wherein each of the material layers has a thickness of greater than or equal to about 15 nm to less than or equal to about 150 nm.

24. The radiofrequency (RF)-transparent material of claim 21, wherein the multilayer stack comprises three distinct material layers, wherein a first material layer is disposed on the substrate and comprises germanium (Ge), a second material layer is disposed over the first layer and comprises silicon dioxide (SiO₂), and a third terminal material layer is disposed over the second layer and comprises germanium (Ge).

25. The radiofrequency (RF)-transparent material of claim 21, wherein a first material layer is disposed on the substrate and comprises germanium (Ge) and has a first average thickness of about 33 nm, a second material layer comprises silicon dioxide (SiO₂) disposed on the first material layer and has a second average thickness of about 119 nm, and a third layer comprises germanium (Ge) disposed on the second layer that has a third average thickness of about 21 nm.

26. The radiofrequency (RF)-transparent material of claim 21, further comprising a protective coating disposed over a terminal end of the multilayer stack that is transparent to electromagnetic radiation in the visible light range.

27. The radiofrequency (RF)-transparent material of claim 21, wherein the substrate is selected from the group consisting of: polymer, an inorganic dielectric material, and combinations thereof.

28. A device comprising the radiofrequency (RF)-transparent material of claim 20, wherein the device is selected from the group consisting of: a decoration, a vehicle component, trim, a consumer product, a mobile device, a wall, a section of a wall, a security device, and combinations thereof.

29. A material having a chrome-like appearance comprising:
a substrate; and
a multilayer stack disposed on the substrate that comprises at least three material layers, wherein at least two material layers are compositionally distinct from one another and each material layer independently comprises a composition selected from:
a first composition comprising an optically transparent dielectric material selected from the group consisting of: titanium oxide (TiO₂), silicon dioxide (SiO₂), magnesium fluoride (MgF₂), magnesium oxide (MgO), aluminum oxide (Al₂O₃), hafnium oxide (HfO₂), zirconium dioxide (ZrO₂), zinc sulfide (ZnS), zinc selenide (ZnSe), zinc oxide (ZnO), silicon nitride (Si₃N₄), silicon dioxide (SiO₂), tin oxide (SnO₂), and combinations thereof;
a second composition comprising a light absorbing material comprising an element selected from Groups 13 to 16 of the IUPAC Periodic Table;
a third composition comprising a light reflecting material selected from the group consisting of: nickel (Ni), aluminum (Al), copper (Cu), silver (Ag), gold (Au), tungsten (W), zinc (Zn), platinum (Pt), titanium (Ti), titanium nitride (TiN), and combinations thereof; or
a fourth composition comprising chromium (Cr), wherein the material displays a specular reflectivity such that greater than or equal to about 70% of wavelengths in a visible light range of greater than or equal to about 390 nm to less than or equal to about 750 nm are reflected by the material without scattering.

30. A method of making a material having a chrome-like appearance, the method comprising:
depositing at least three material layers on a substrate via a physical vapor deposition process to form a multilayer stack, wherein at least two material layers are compositionally distinct from one another and each material layer independently comprises a composition selected from:
a first composition comprising an optically transparent dielectric material selected from the group consisting of: titanium oxide (TiO₂), silicon dioxide (SiO₂), magnesium fluoride (MgF₂), magnesium oxide (MgO), aluminum oxide (Al₂O₃), hafnium oxide (HfO₂), zirconium dioxide (ZrO₂), zinc sulfide (ZnS), zinc selenide (ZnSe), zinc oxide (ZnO), silicon nitride (Si₃N₄), silicon dioxide (SiO₂), tin oxide (SnO₂), and combinations thereof;
a second composition comprising a light absorbing material comprising an element selected from Groups 13 to 16 of the IUPAC Periodic Table; or
a third composition comprising a light reflecting material selected from the group consisting of: nickel (Ni), aluminum (Al), copper (Cu), silver (Ag), gold (Au), tungsten (W), zinc (Zn), platinum (Pt), titanium (Ti), titanium nitride (TiN), and combinations thereof, wherein the material is free of chromium (Cr) and displays a specular reflectivity such that greater than or equal to about 50% of wavelengths in a visible light range of greater than or equal to about 390 nm to less than or equal to about 750 nm are reflected by the material without scattering.

31. The method of claim 30, wherein the depositing at least three material layers on a substrate via a physical vapor deposition process occurs via an electron beam evaporation, thermal evaporation, or a sputtering process.

32. The method of claim 30, wherein each material layer of the at least three material layers are deposited sequentially on the substrate.

33. The method of claim 30, wherein each material layer of the at least three material layers has an average thickness of greater than or equal to about 15 nm to less than or equal to about 150 nm.

34. The method of claim 30, wherein the multilayer stack comprises from three to five material layers.

35. The method of claim 30, wherein each material layer is independently selected from the first composition or the second composition, wherein the material is free of any metals, and displays a transparency to radiofrequency (RF) electromagnetic radiation where greater than or equal to about 60% of wavelengths of greater than or equal to about 1 mm to less than or equal to about 10 m are transmitted.
